(19) United States
(12) Patent Application Publication
(10) Pub. No.: US 2025/0337488 A1
(43) Pub. Date: Oct. 30, 2025

(54) OPTICAL DATA SIGNAL RECEIVER

(71) Applicant: Top Integrated Circuits Ltd, Southampton (GB)

(72) Inventors: Penelope GOULD, Southampton (GB); Patrick RICHARD, Southampton (GB); William REDMAN-WHITE, Southampton (GB)

(21) Appl. No.: 19/190,364

(22) Filed: Apr. 25, 2025

(30) Foreign Application Priority Data
Apr. 25, 2024 (GB) 2405850.5

(51) Int. Cl. H04B 10/077; H04B 10/69

(52) U.S. Cl. CPC H04B 10/0779; H04B 10/6931

(57) ABSTRACT

An assembly of electronic components for reception of data using an optical fiber wherein data is received in bursts, the assembly comprising: a photodiode; a transimpedance amplifier coupled to said photodiode, the gain of the transimpedance amplifier being adjusted based on a level of a gain control signal: a received input signal sensor configured to sense a received input signal level and provide the gain control signal, the gain control signal being varied according to the received input signal level; wherein the received input signal level is sensed via a sampling circuit arrangement; a comparator; and an adjustor for adjusting a low-frequency behavior and a high-frequency behavior of the comparator so that the detection of both positive data symbol level transitions and negative data symbol level transitions in the received signal have identical behavior within accepted engineering tolerances.

### FIELD OF THE INVENTION

Some embodiments relate to a system and method for receiving optical signals.

### BACKGROUND

The invention is concerned with the operation of an optical line terminal (OLT) unit, as used as the hub of a passive optical network (PON) used for the communication of data to and from a central hub to a number of client optical network units (ONU).

In such a system it is common for data that are to be sent from the individual ONUs to the OLT to be transmitted separated in time as short data bursts, a form of time-division multiplexing. Due to different optical path lengths from each ONU as well as other factors, the strength of the optical signals for each received burst may vary significantly from data burst to data burst.

The problem to be addressed is the manner in which the OLT receiver handles data bursts of differing signal strengths from different ONUs which are separated in time by short intervals. For each data burst the receiver electronic system must set the amplification level and other system parameters so that the information can be recovered successfully in the succeeding electronics. The receiving path electronic system should preferably adapt its characteristics to the signal strength of each incoming burst in a very short time interval, with typically a very short training signal available in a preamble period prior to the data payload. This adaptation should also preferably be performed with a settling time that is consistent for the wide range of signal levels and different data rates expected for each different burst. The adaptation should also preferably adjust the settling time dependent on the presence of a training preamble or the presence of payload data so as to provide control over the system gain that is optimised for both situations. The means provided for controlling the adaptation of the amplification and settling in response to each individual data burst should also preferably be insensitive to errors and imperfections in the electronic circuitry comprised therein, or be able to be adjusted in a convenient manner in order to take such errors and imperfections into account.

It is an object of the invention to provide means for the calibration of a clocking system, said clocking system being used to control the sampling of the TIA output for the TIA AGC system, such that both low frequency and high frequency imperfections in the sample clock generation circuits are minimised.

### SUMMARY

According to an aspect of the invention there is provided a system comprising: an assembly of electronic components for reception of data using an optical fibre wherein data is received in bursts, and wherein said assembly comprises: a photodiode; a transimpedance amplifier coupled to said photodiode, wherein said the gain of said transimpedance amplifier is adjusted based on a level of a gain control signal, and wherein said transimpedance amplifier comprises; a first amplifier; a network of electronic components presenting an impedance between two terminals, wherein one terminal of said network of electronic components presenting said impedance is coupled to an output of said first amplifier and another terminal of said network of electronic components presenting said impedance is coupled to an input of said first amplifier; a received input signal sensor is configured to sense a received input signal level, wherein said received input signal sensor is configured to provide a first control signal, said first control signal being varied according to said received input signal level, wherein said received input signal sensor further comprises: an integrator or filter for smoothing said first control signal, an output of said integrator or filter being said gain control signal; a sampler for sampling said received input signal, wherein said sampler takes samples of said received input signal at sampling instants dependent on an occurrence of data symbol level transitions in said received input signal; a comparator configured to detect data symbol level transitions in said received input signal and wherein the sampling instants of said sampler are derived from an output of said comparator; and an adjustor for adjusting a low frequency behaviour and a high frequency behaviour of said comparator so that said detection of both positive data symbol level transitions and negative data symbol level transitions in said received signal have identical behaviour within accepted engineering tolerances, and wherein said adjustor further comprises: a calibration controller; a low frequency calibration arrangement; a high frequency calibration arrangement.

The comparator may have differential inputs and complementary logical outputs, and wherein the logical high values of each of said complementary outputs are identical within accepted engineering limits, and wherein the logical low values of each of said complementary outputs are identical within accepted engineering limits.

At least one input of said comparator may be connected to said received signal via at least one capacitor.

The comparator may be configured to be disconnected from said received signal and configured to receive a low frequency ramp calibration input with defined levels.

The low-frequency calibration arrangement may be configured to analyse decisions of said comparator generated in response to a low frequency ramp calibration input with defined levels.

The low-frequency calibration arrangement may be configured to reduce any lack of symmetry between positive going and negative going decision levels of said comparator to a negligible magnitude by adjustment of said adjustor under control of said low-controller.

The high frequency calibration arrangement may comprise a passive low-pass filter connected to each of the complementary outputs of said comparator, and wherein a cut-off frequency of said passive low-pass filter is significantly below a lowest frequency component expected in said received signal when said assembly of electronic components is configured to receive said signals.

The input from said photodiode may be disconnected and a high-frequency test signal is applied to an input of said transimpedance amplifier.

The high frequency calibration arrangement may further comprise a high-frequency signal source, wherein said high-frequency signal source provides said high-frequency test signal, said high-frequency test signal having a frequency comparable with a frequency of a preamble pattern that occurs in said data bursts, and wherein said high-frequency test signal has a magnitude comparable with a magnitude of a signal received from said photodiode, and wherein said high-frequency test signal has a substantially square waveform with a mark: space ratio that is equal within accepted engineering tolerances.

The outputs of said passive low-pass filters may be compared and a difference between a DC level present on each passive low-passive filter output passed to said calibration controller, said high-frequency calibration arrangement being configured to be able to reduce a difference between DC levels of said outputs of said low-pass filters to a negligibly small value by adjustment of said adjustor under the control of said calibration controller.

According to a second aspect of the invention there is provided a method for the reception of data using an optical fibre wherein data is received in bursts, and wherein said method comprises: providing a photodiode; providing a transimpedance amplifier coupled to said photodiode, wherein said gain of said transimpedance amplifier is adjusted based on a level of a gain control signal, and wherein said transimpedance amplifier comprises; a first amplifier; a network of electronic components presenting an impedance between two terminals, wherein one terminal of said network of electronic components presenting said impedance is coupled to an output of said first amplifier and another terminal of said network of electronic components presenting said impedance is coupled to an input of said first amplifier; providing a received input signal sensor configured to sense a received input signal level, wherein said received input signal sensor is configured to provide a first control signal, said first control signal being varied according to said received input signal level, wherein said received input signal sensor further comprises: an integrator or filter for smoothing said first control signal, an output of said integrator or filter being said gain control signal; a sampler for sampling said received input signal, wherein said sampler takes samples of said received input signal at sampling instants dependent on an occurrence of data symbol level transitions in said received input signal; a comparator configured to detect data symbol level transitions in said received input signal and wherein the sampling instants of said sampler are derived from an output of said comparator; and an adjustor for adjusting a low frequency behaviour and a high frequency behaviour of said comparator so that said detection of both positive data symbol level transitions and negative data symbol level transitions in said received signal have identical behaviour within accepted engineering tolerances, and wherein said adjustor further comprises: a calibration controller; a low frequency calibration arrangement; and a high frequency calibration arrangement.

Said comparator may have differential inputs and complementary logical outputs, wherein the logical high values of each of said complementary outputs are identical within accepted engineering limits, and wherein the logical low values of each of said complementary outputs are identical within accepted engineering limits.

At least one input of said comparator may be connected to said received signal via at least one capacitor.

Said comparator provided in said method may be configured to be disconnected from said received signal and configured to receive a low frequency ramp calibration input with defined levels.

Said low-frequency calibration arrangement provided in said method may be configured to analyse decisions of said comparator generated in response to said low frequency ramp calibration input with defined levels.

Said low-frequency calibration arrangement provided in said method may be configured to reduce any lack of symmetry between positive going decision levels and negative going decision levels of said comparator to a negligible magnitude by adjustment of said adjustor under control of said calibration controller.

Said high frequency calibration arrangement provided in said method may comprise a passive low-pass filter connected to each of the complementary outputs of said comparator, wherein a cut-off frequency of said passive low-pass filter is significantly below a lowest frequency component expected in said received signal when said assembly of electronic components is configured to receive said signals.

An input from said photodiode provided in said method may be disconnected and a high-frequency test signal applied to an input of said transimpedance amplifier.

Said high frequency calibration arrangement provided in said method may further comprise a high-frequency signal source, wherein said high-frequency signal source provides said high-frequency test signal, said high-frequency test signal having a frequency comparable with a frequency of a preamble pattern that occurs in said data bursts, and wherein said high-frequency test signal has a magnitude comparable with a magnitude of a signal received from said photodiode, and wherein said high-frequency test signal has a substantially square waveform with a mark: space ratio that is equal within accepted engineering tolerances.

The outputs of said passive low-pass filters provided in said method may be compared and a difference between a DC level present on each passive low-passive filter output passed to said calibration controller, said high-frequency calibration arrangement being further configured to be able to reduce a difference between DC levels of said outputs of said low-pass filters to a negligibly small value by adjustment of said adjustor under the control of said calibration controller.

### BRIEF DESCRIPTION OF FIGURES

The invention will now be described solely by way of example and with reference to the accompanying drawings in which:

FIG. 1 shows a typical arrangement for a passive optical network system according to prior art illustrating bursts of different amplitudes and extinction ratio present during operation of the system.

FIG. 2 illustrates the properties and timing specification parameters of a typical data burst employed in a passive optical network according to prior art.

FIG. 3 shows a typical arrangement for input circuitry in a PON receiver according to prior art wherein there are separate time constants present for DC removal and automatic gain control.

FIG. 4 illustrates the form of behaviour expected in a PON receiver according to prior art wherein the AGC response has a slow fixed time constant.

FIG. 5 illustrates the form of behaviour expected in a PON receiver according to prior art wherein the AGC response has a fast fixed time constant.

FIG. 6 shows an arrangement for a PON receiver according to an aspect of the invention wherein the AGC time constant varies according to the data transition density in the burst.

FIG. 7 illustrates the form of behaviour expected in a PON receiver according to an aspect of the invention wherein the AGC response has a time constant that changes from fast to slow before the end of the preamble in the data burst.

FIG. 8 shows an arrangement for a PON receiver according to an aspect of the invention wherein the AGC is controlled by a circuit containing a switched capacitor signal path and wherein the sampling of the switched capacitors is controlled by transitions in the incoming data.

FIG. 9 illustrates the derivation of sampling control signals from the incoming signal according to an aspect of the invention wherein transitions on each edge of the incoming data can be used to provide sampling control signals for switched capacitor circuits employed in the control of the AGC. (Data waveform samples taken at predictable instants).

FIG. 10 shows an arrangement for a PON receiver according to an aspect of the invention wherein the AGC is controlled by a circuit containing a switched capacitor signal path and wherein the sampling of the switched capacitors is controlled by a circuitry containing a divider controlled by transitions in the incoming data.

FIG. 11 illustrates the derivation of sampling control signals from the incoming signal preamble according to an aspect of the invention wherein transitions on each edge of the incoming data can be used to control an odd number divider to provide sampling control signals for switched capacitor circuits employed in the control of the AGC. (Data waveform samples taken at predictable instants).

FIG. 12 illustrates the derivation of sampling control signals from the incoming signal during the data payload according to an aspect of the invention wherein transitions on each edge of the incoming data can be used to control an odd number divider to provide sampling control signals for switched capacitor circuits employed in the control of the AGC. (Data waveform samples taken at predictable instants).

FIG. 13 shows an arrangement for a PON receiver according to an aspect of the invention wherein a comparator employed in the provision of sampling signals for switched capacitor circuitry in the AGC system is AC coupled to a signal path.

FIG. 14 illustrates an ideal behaviour for a comparator with hysteresis such as may be employed in the provision of sampling signals for switched capacitor circuitry in the AGC system.

FIG. 15 shows an arrangement for a PON receiver according to an aspect of the invention wherein there is provided means for calibrating the DC and AC performance of a comparator employed in the provision of sampling signals for switched capacitor circuitry in the AGC system.

FIG. 16 illustrates a method according to an aspect of the invention for calibrating the DC and AC performance of a comparator employed in the provision of sampling signals for switched capacitor circuitry in the AGC system.

FIG. 17 shows an arrangement for a PON receiver according to an aspect of the invention wherein a time constant in the AGC circuitry may be changed from fast to slow by means of changing the resistance seen in the input signal path, and wherein the change in the signal path resistance is controlled by timing circuitry that determines the duration or end of the preamble.

FIG. 18 shows an arrangement for a PON receiver according to an aspect of the invention wherein a time constant in the AGC circuitry may be changed from fast to slow by means of connecting an additional capacitor, and wherein the connection of said capacitor is controlled by timing circuitry that determines the duration or end of the preamble.

FIG. 19 shows an arrangement for detecting the end of the preamble in a burst mode PON receiver according to an aspect of the invention wherein a detection threshold level is set during the preamble.

FIG. 20 shows an arrangement for detecting the end of the preamble in a burst mode PON receiver according to an aspect of the invention wherein a ramp signal controlled by data transitions does not cross a previously set detection threshold level during the preamble.

FIG. 21 shows an arrangement for detecting the end of the preamble in a burst mode PON receiver according to an aspect of the invention wherein a ramp signal controlled by data transitions crosses a previously set detection threshold level during the data payload and produces a signal indicating that the preamble has ended.

FIG. 22 shows an arrangement for detecting the end of the preamble in a burst mode PON receiver according to an aspect of the invention wherein a ramp signal controlled by data transitions wherein a crossing of said ramp signal of said detection threshold level is detected by a comparator clocked at a following data transition before said ramp is reset.

FIG. 23 illustrates the behaviour of an arrangement for detecting the end of the preamble in a burst mode PON receiver according to an aspect of the invention wherein a ramp signal controlled by data transitions wherein a crossing of said ramp signal of said detection threshold level is detected by a comparator clocked at a following data transition before said ramp is reset and provides a signal indicating that the preamble has ended.

### DETAILED DESCRIPTION

Whilst this invention has been described with reference to particular examples and possible embodiments thereof these should not be interpreted as restricting the scope of the invention in any way. It is to be made clear that many other possible embodiments, modifications and improvements may be incorporated into or with the invention without departing from the scope and spirit of the invention as set out in the claims.

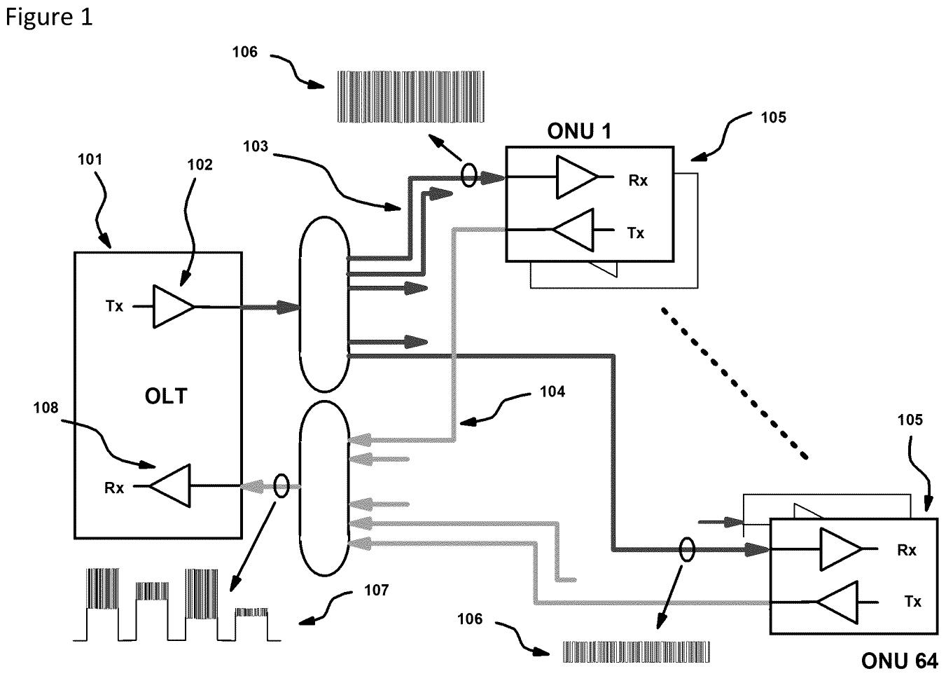

FIG. 1 shows typical arrangements in a transceiver suitable for an optical communications system. Within an optical line terminal (OLT) 101, a transmitter 102 transmits data in the form of optical signals 106, wherein said optical signals are connected effectively in parallel to a number of separate optical fibres 103 that convey said data signals to a number of separate optical network units (ONUs) 105.

Each of these fibres to 103 and from 104 each ONU 105 may be of different lengths, and thus it is likely that the optical signal received by each ONU will be somewhat different in strength from the signal received at some other ONU. This variation is not a major problem for the ONU receive path, since the signals to be received are effectively constant in value for each successive data burst, with only slow variation due to environmental changes. As such, the gain control setting for the ONU 105 receive circuitry may be determined in some initial transmission protocol and can therefore be kept relative fixed for the duration of any period of activity.

The situation is somewhat more complex for signals 107 transmitted by the ONUs 105 back to the OLT 101. Even if the magnitude of the transmitted optical signal is the same for each ONU, due to the likelihood of there being different fibre path lengths 104, the magnitudes of the signals 107 received by the OLT receiver 108 may be different for each successive burst received. Consequently, the gain setting of the OLT receiver 108 circuitry must be reset for each burst and optimised for the strength of each particular burst. Further, this gain setting optimisation process must be undertaken expeditiously and effectively complete within the preamble period of that burst. Further, there is limited information provided at the system level to steer this gain setting process.

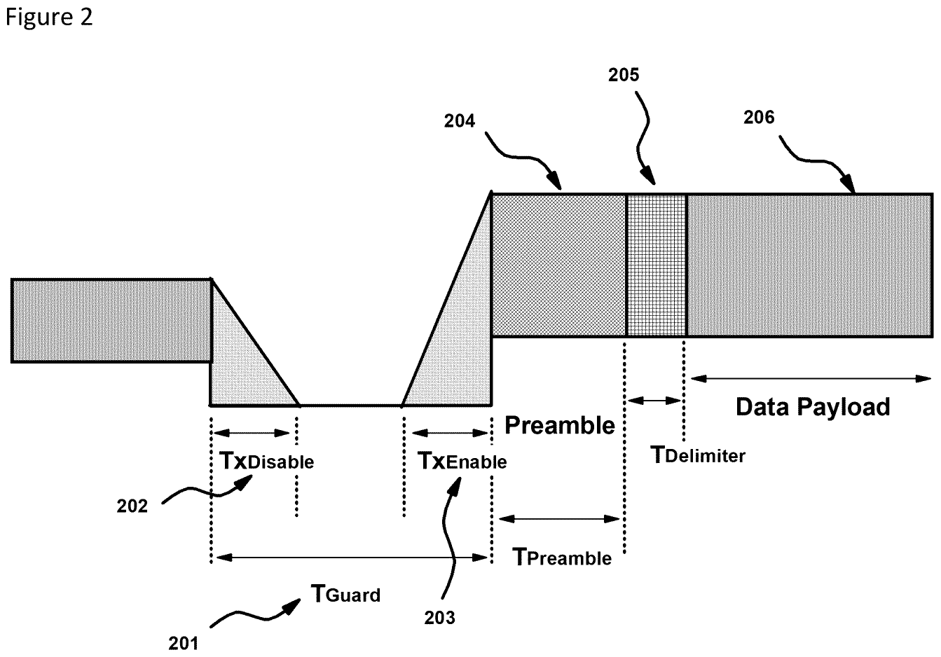

FIG. 2 illustrates a typical timing specification for data bursts. Between the end of one burst and the start of another burst there is a designated guard time 201 TGuard, which has a minimum value, typically of the order of 100 nanoseconds. Within this guard time and at the end of a burst there is a defined period 202 TxDisable set aside for disabling the transmit path and laser driver in a particular ONU or OLT. At the end and within the guard interval there is a defined period 203 TXEnable set aside for activating the transmit path and laser driver in a particular ONU or OLT. At the beginning of a new data burst there is an initial period during which a defined preamble signal pattern 204, typically a continuous balanced pattern, such as a ‘1010’ pattern, is transmitted with the purpose of providing a known signal to allow the intended receiver to adjust its gain and possibly other parameters to optimise the reception of that burst. The preamble may have a defined minimum duration specified to allow the receiver to successfully adjust circuit parameters.

Following the preamble, some form of delimiter pattern 205 indicates that the data payload 206 is about to begin. When the signal changes from the preamble to the data payload, the data pattern will typically change from a ‘1010’ pattern with a high density of transitions, to a more random pattern with potentially longer intervals where there is no transition, and the incoming signal may remain constant at either the ‘1’ or ‘0’ for several unit time intervals of the prevailing data rate. This latter consideration affects the choice of settling time constant that may be used in the AGC of a receiver signal path. A fast settling time, preferred to establish an optimum setting during the preamble, will tend to degrade the quality of the signal remaining at a ‘1’ or a ‘0’ state for multiple unit intervals, and cause a drift away from the optimum level.

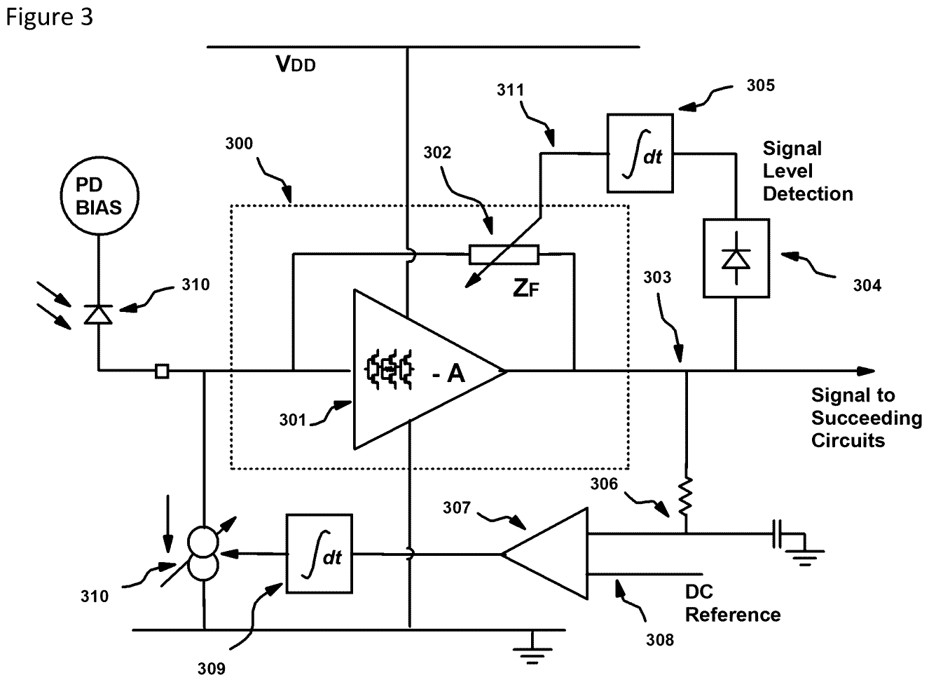

In FIG. 3 shows a typical arrangement for a transimpedance amplifier (TIA) 300 as may be used in the input circuitry in a PON receiver according to prior art. An amplifier 301 has a feedback path 302 which may be purely resistive or comprise a combination of resistive and reactive components. This arrangement takes the signal current from the photodiode 310 and converts it to a signal voltage, being more convenient for subsequent signal processing circuitry.

In such a TIA arrangement, it is common practise to have two separate automatic control loops within the TIA. Firstly, there may be a control loop whose purpose is to set the gain of the amplifier system so that the output of the amplifier remains at a substantially constant level despite wide variations in the incoming optical signal amplitude, commonly referred to as the automatic gain control (AGC) system. Typically, the resistance (or impedance) of a feedback network 302 is adjusted in response to the detected magnitude of the signal present at the output of the TIA 303. In many situations, the TIA output signal 303 will be AC coupled to a signal detection function 304. The output of the signal detection function is passed through an integrator 305 or low-pass filter to provide a smooth control signal 311 to adjust the resistance (or impedance) of the feedback network 302.

In addition to the AGC function, it is common to employ a second loop to remove the DC component of the photodiode current. This is desirable since the average DC value present in the photodiode current will vary depending on the strength of the optical signal (as well as on other factors such as temperature). This DC component of the photodiode signal may be amplified by the TIA 300, and in extreme cases, lead to the amplifier response saturating, with its output limited at one or other maximum output values, leading to the blocking of any signal throughput.

To remove this risk of saturating the TIA 300, the DC voltage level 306 at the output of the TIA may be applied to a differential amplifier 307, said amplifier being used to compare the TIA output with a convenient reference level 308 and the error signal produced may then be used to drive an integrator or low pass filter 309. The integrated (or filtered) DC error signal may then be used to control a variable current source 310 that may be used to remove the DC component of the photodiode 310 current from the input of the TIA 300. In this way, the TIA output 303 is effectively just the AC component of photodiode signal, representing the data signal being received.

Whilst the use of separate AGC and DC removal/restoration functions is convenient in a TIA receiving continuous signals, or one receiving repetitive bursts of near identical magnitudes, there are problems where signal levels can fluctuate widely between successive data bursts. In the latter case, it becomes necessary for two separate control loops to settle to an optimum value within the time allotted to the burst preamble. It will be apparent to one skilled in the art that as well as being a very difficult task, the presence of two separate integration or filtering functions within the TIA arrangement presents a significant risk of instability.

To simplify the settling problem, the TIA may be designed in such a way that it is able to cope with the variations in the DC component of the photodiode current over the required range of optical inputs. The large variations in the common mode level at the output of the TIA must therefore be accommodated in the subsequent signal conditioning and processing circuits.

Whilst not incorporating a photodiode DC control loop in the TIA helps to avoid any instability in the TIA, it still leaves the problems associated with the choice of time constant to be used in the AGC.

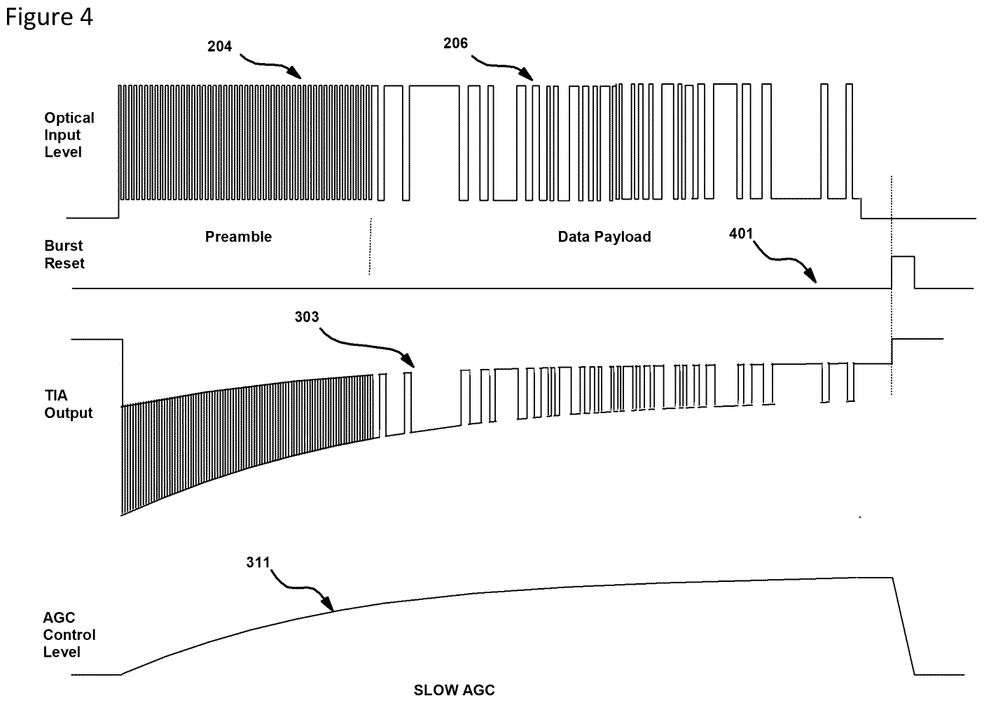

FIG. 4 illustrates typical behaviour of the AGC system with a relatively long time constant. When a burst arrives with the system following a reset state 401, as would be the case for an OLT receiving burst from a variety of different ONUs, it will be seen that the AGC control 311 is not fully settled by the finish of the preamble pattern 204, and the optimum conditions are not set for the TIA output 303 when the system is required to recover the data from the signal during the data payload period 206. Further, at the start of the burst the AGC system will typically set the gain to a maximum value, and hence there is a possibility that the TIA output 303 remains saturated after the end of the preamble if the optical input signal is strong. Obviously, during the data payload 206 the slow AGC settling can have some benefits as it does not respond rapidly to the effects of varying pattern density due to the data itself, but a slower settling during the payload is not beneficial if the AGC has not settled sufficiently during the preamble.

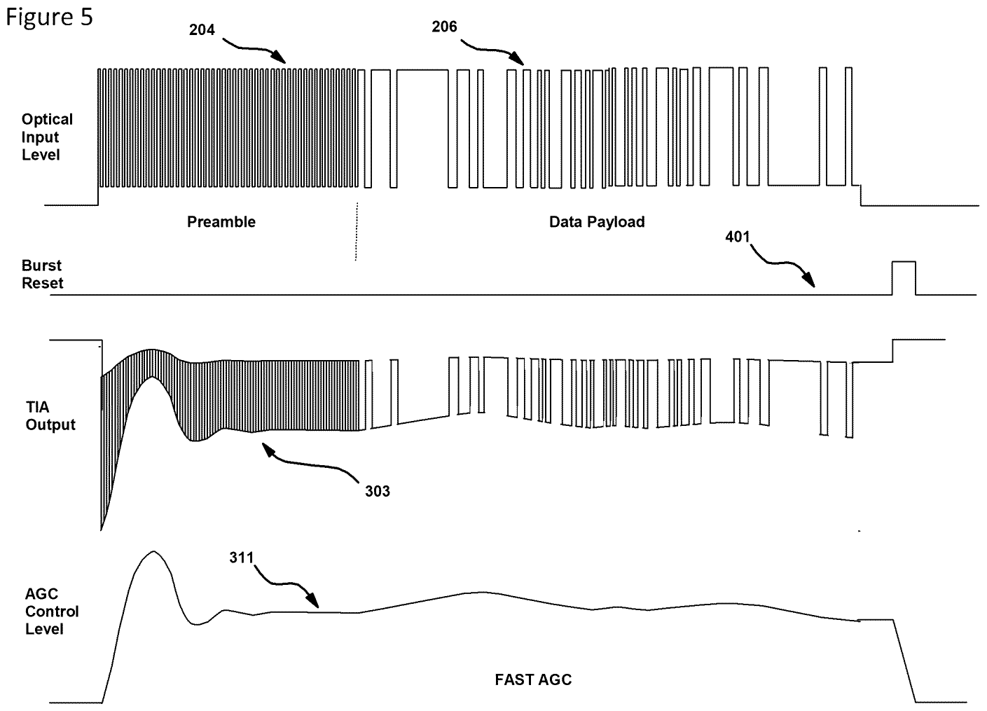

FIG. 5 shows a representation of the behaviour of a system wherein the AGC settling is configured to be relatively fast. In this case, it is possible for the AGC control signal 311 to settle within the duration of the preamble even if the system is reset 401 prior to the arrival of the data burst. However, the fast response of the AGC system leads its settled level being sensitive to the data pattern during the payload. If there are long sequences of consecutive ‘1’ or ‘0’ data values present in the data being received, it will be apparent to one skilled in the art that the AGC will respond to the short-term average level of the TIA output 303 being either high or low compared with the ideal common mode level. Hence the AGC level 311 will not remain at the optimum level for the recovery of the data values from the TIA output signal 303 by the succeeding signal conditioning and processing circuitry.

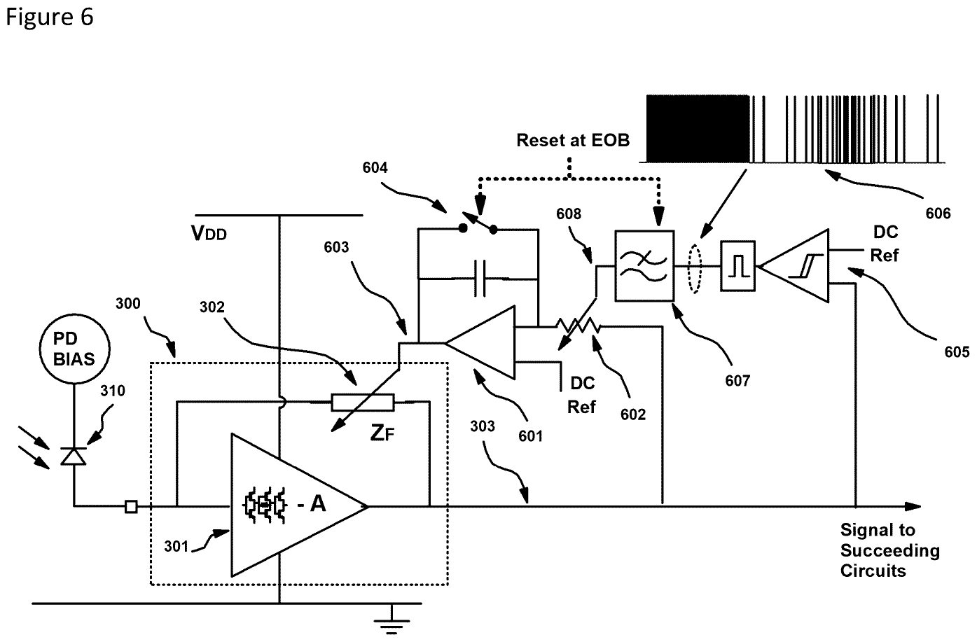

FIG. 6 shows an arrangement for a TIA system that addresses the abovementioned problems according to an aspect of the invention. There is provided an AGC control loop comprising an integrator 601 whose input is taken from the output 303 of the TIA 300 via a resistance 602. The output of said integrator 603 is used to control the gain of the TIA 300, ether by means of varying the resistance (or impedance) of the feedback path 302, or by means of varying the gain of the amplifier core 301 within the TIA configuration 300. There is also provided means 604 to reset the integrator 601 between data bursts, a process that may be activated by externally provided system level signals.

In order to obtain improved settling of the AGC level within the preamble 204 and yet reduce sensitivity to data pattern density during the payload 206, the settling time of the integrator 601 controlling the AGC level is made to be variable, for example, by means of control over the said resistance 602 used by the AGC system to sense the output 303 of the TIA 300.

To control the speed of the AGC settling at any given instant, there is provided a system that detects the occurrence and density of data transitions. In the arrangement shown in FIG. 6, this function is provided by detecting data transitions using a comparator 605, and from these decisions, generating identical duration and amplitude pulses 606 at each data transition. Smoothing these pulses using a low pass filter 607 provides a signal 608 proportional to the density of data transitions. Hence, when the density of data transitions is high, as in the preamble 204, the AGC settling time is adjusted to a faster response. When the data density reduces, as would be expected during the data payload 206, the AGC settling time is adjusted to be slower, so that sensitivity to consecutive identical symbol sequences is reduced.

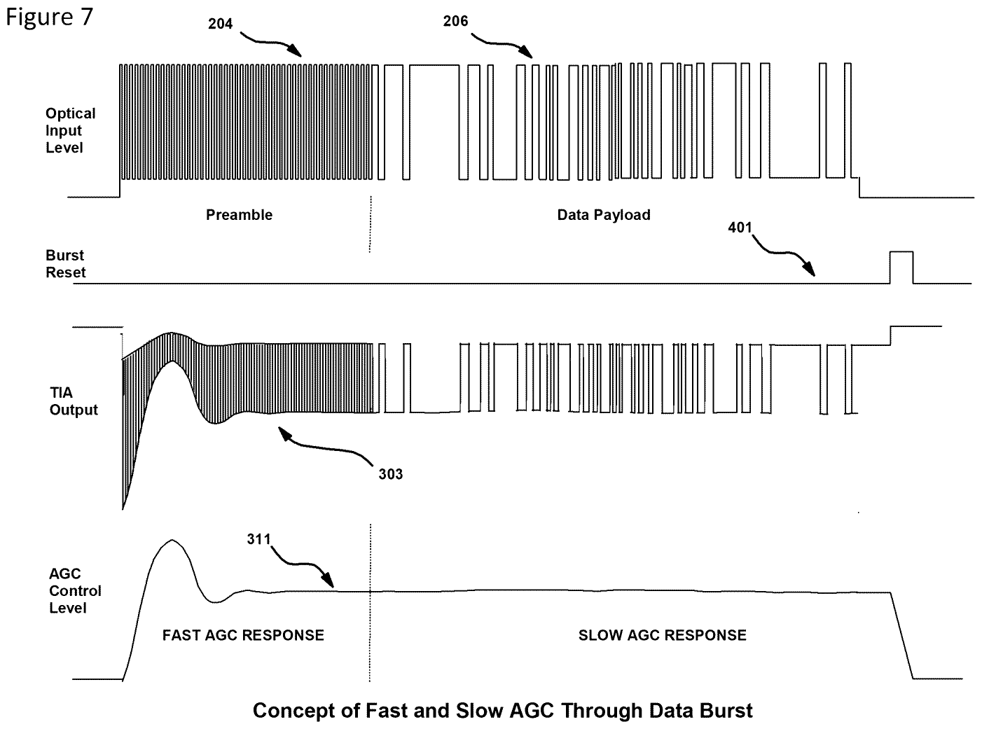

FIG. 7 gives a representation of the behaviour of a TIA system wherein there is provided an arrangement whereby the AGC settling time is adjusted according to the detected density of data transitions, such as shown in FIG. 6. It will be seen that the AGC control level 311 settles to an optimum condition within the duration of the preamble 204 when the density of data transitions is high. During the data payload interval 206, the settling of the AGC control level 311 slows down and the response to any sequences of consecutive identical data symbols is reduced to minimal levels.

It will be apparent to one skilled in the art that whilst the arrangement illustrated in FIG. 6 presents a possible solution to the need for the AGC settling behaviour to take account of data transition density, there remains a potential issue insofar as the data transition detection arrangement in FIG. 6 has within it a settling time constant. Whilst this is unlikely to provoke instability within the TIA system as a whole, it places a restriction on the speed with which the AGC settling time can respond to data transition density changes. On the one hand, it would be desirable for the smoothing of the data transition information to be fast, but this could have the potential for injecting noise into the AGC control loop via the variable element in the AGC integrator (or filter). On the other hand, if the smoothing time constant for the data transition information is slow, then the AGC settling time constant is not likely to be able to respond fast enough to reduce sensitivity to consecutive identical data symbols after the end of the preamble.

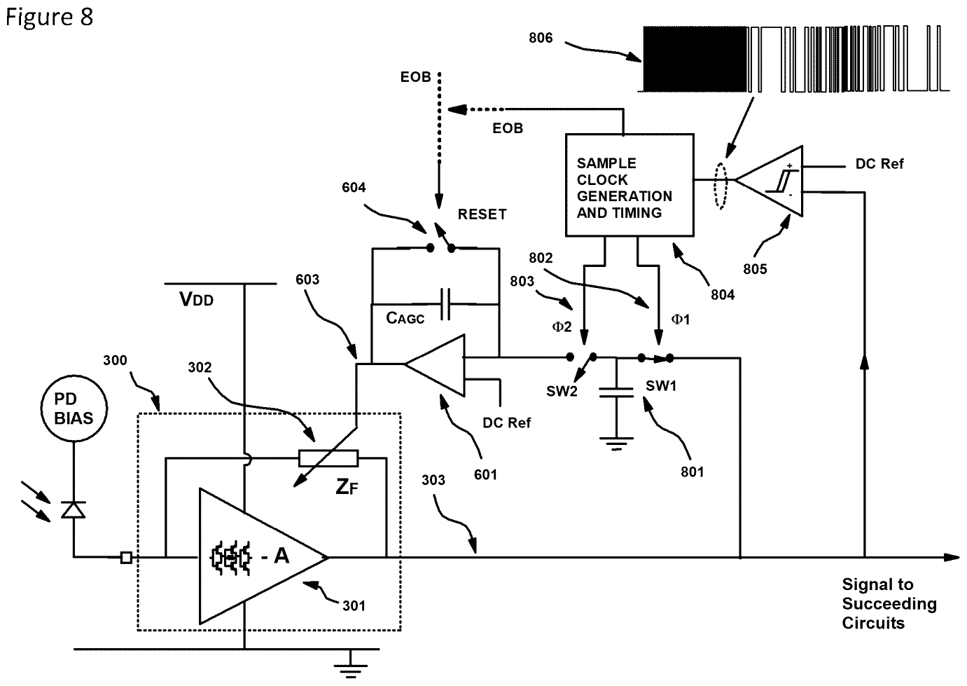

FIG. 8 shows a further arrangement for a TIA system wherein the AGC settling time is dependent on the density of data transitions according to an aspect of the invention. There is provided an integrator function 601 which generates the AGC control signal 603 to set the overall gain of the TIA 300. The output of said integrator is used to control the gain of the TIA 300, ether by means of varying the resistance (or impedance) of the feedback path 302, or by means of varying the gain of the amplifier core 301 within the TIA configuration. There is also provided means 604 to reset the integrator 601 between data bursts, a process that may be activated by externally provided system level signals or may be initiated by some timing system 804 within the TIA system itself.

Rather than use a conventional resistive input for the integrator, there is provided an input that samples the TIA output by means of a switched capacitor circuit arrangement 801. The sampling clocks 802, 803, required by said switched capacitor circuit arrangement 801 are provided by a sample clock generation and timing function 804, which is in turn provided with timing information from a comparator 805 that detects transitions in the data waveform present at the output 303 of the TIA 300. Preferably, the comparator employs a degree of hysteresis in its operation in order to prevent false responses under low signal conditions at the output of the TIA.

By the use of a switched capacitor input to the integrator, it will be apparent that the settling time of the AGC becomes directly related to the data transition density, since the input charge per unit of time, equivalent to a smooth current, as provided to the integrator 601 is directly related to the individual sampling cycles of the said switched capacitor arrangement 801. In this way, any issues related to delay or smoothing in a data density detection scheme such as shown in FIG. 6 are avoided, and a more ideal AGC settling time regime is provided.

Note that it is preferable to derive sampling clock information from both rising and falling edges of the comparator output 806, in order that the TIA output signal 303 may be sampled in a symmetrical fashion that does not impart an inherent offset into the integrator 601 input.

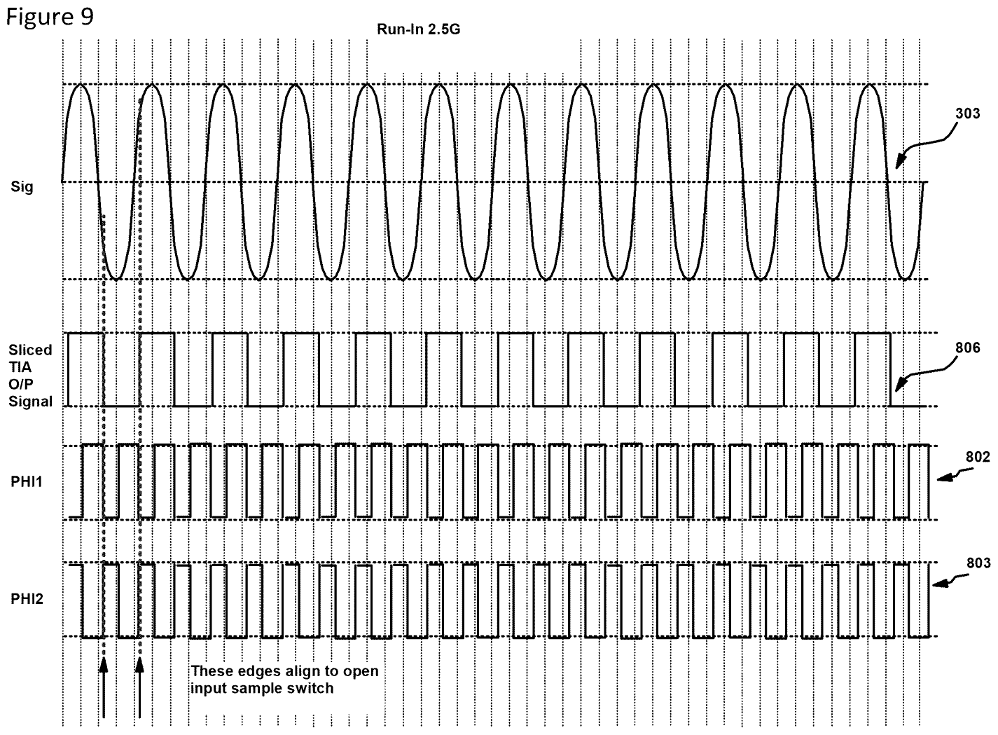

FIG. 9 illustrates a possible sampling scheme wherein the sampling clocks 802, 803, are derived from both rising and falling edges seen at the output 806 of the comparator 805 providing a sliced version of the amplified data waveform. The sampling clocks may be generated using a pulse generator or other means so that each edge creates a full cycle of each sampling clock. In FIG. 9 the sampling process is illustrated as being during the preamble 204 where the data pattern is assumed to be a balanced ‘1010’, and the data rate is such that the sampling circuitry is able to operate at the symbol rate without compromise. It will be seen that the sampling takes place both during the ‘1’ and ‘0’ symbol periods, albeit not necessarily at exact peaks or troughs in the data waveform at the output 303 of the TIA 300. The exact instant of the sampling process will depend on any time delays in the sample clock generation system 804, but as long as the sampling is symmetrical in time with respect to the data transition instants, then the sampling will provide an input equivalent to the mean common mode value of the data waveform, as is desired for correct operation of the AGC system.

In the case that the data symbol rate is very fast, such that the sample clocks cannot be conveniently derived directly from the data transitions, it may become necessary to create sampling clocks that are at a lower rate compared with the symbol rate, but still fulfil the requirement of taking samples equally from the data ‘1’ and data ‘0’ values.

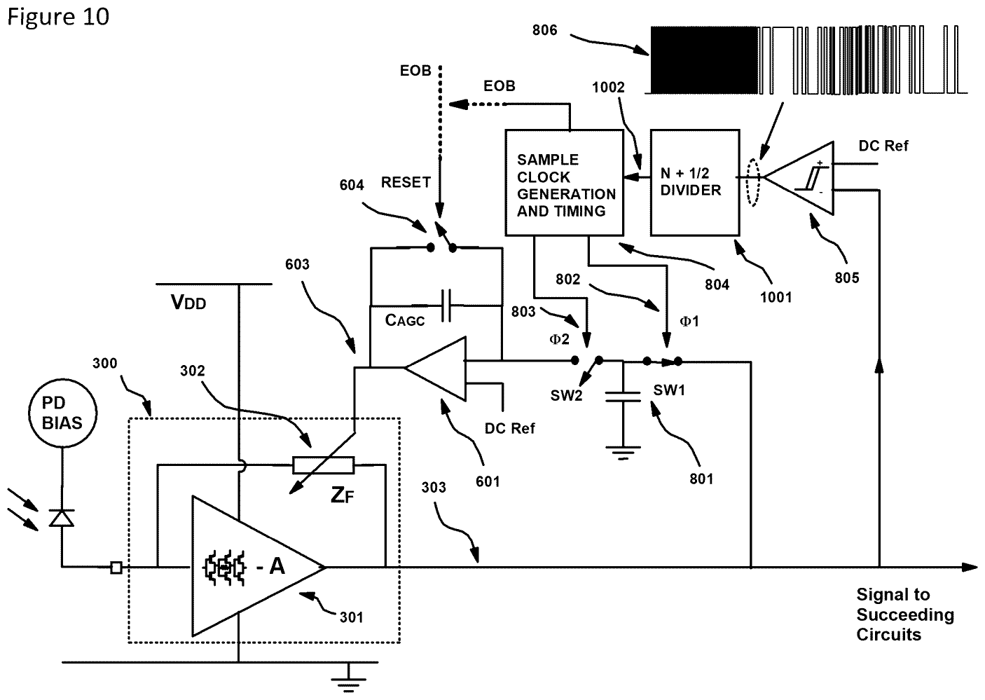

FIG. 10 shows a further arrangement for a TIA system according to an aspect of the invention that addresses this requirement for the clocking of the switched capacitor circuitry 801. A divider 1001 is provided that effectively divides the sliced data waveform 806 by a factor of N+½, where N is an integer. One practical way to realise such a function is to use both rising and falling edges of the data transitions from the sliced signal 806 from the TIA output 303 to provide clocks to an odd number divider. The sampling clocks 802, 803, are then generated from the output 1002 of said divider 1001. In one practical example, a divide-by-5 counter may be used, giving an apparent division ratio of 2 ½.

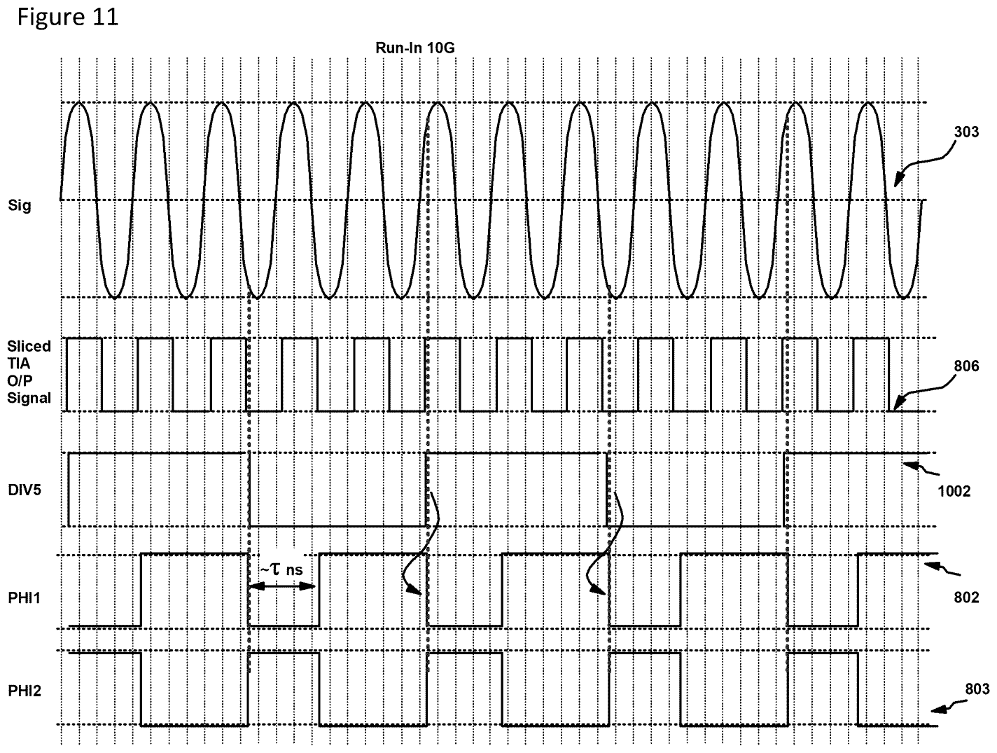

FIG. 11 illustrates how such an odd number division may be used to permit symmetrical sampling of the data signal waveform at the output 303 of the TIA 300, even when the data stream symbol rate is faster than the simple switched capacitor sampling can be reliably clocked. Also shown is a preferred timing scheme whereby the falling edge of the switched capacitor sampling clocks 802, 803, are derived directly from the sliced data transitions 806, whilst the rising edge of the switched capacitor sampling clocks are generated by a time delay element. This derivation of the sampling clocks is preferable, since the falling edges of the sampling clock 802 defines the instant that the TIA output signal 303 is sampled, (assuming that a logical ‘1’ state in either sampling clock ϕ1 802 or ϕ2 803 is taken to set a corresponding switch to a ‘closed’ condition), and hence its timing is critical. The timing of the rising edge of the switched capacitor clock is not so critical, provided that conventional non-overlapping clocking criteria are respected, and hence may conveniently be derived from a time delay element, where the delay is defined with respect to the falling edge of the sampling clock. The sampling of the TIA output signal 303 during a balanced preamble 204, such as a ‘1010’ pattern, is seen to take place evenly on both positive and negative excursions of the data signal waveform, thereby providing an input to the AGC integrator 601 that represents the mean common mode level at the TIA output 303.

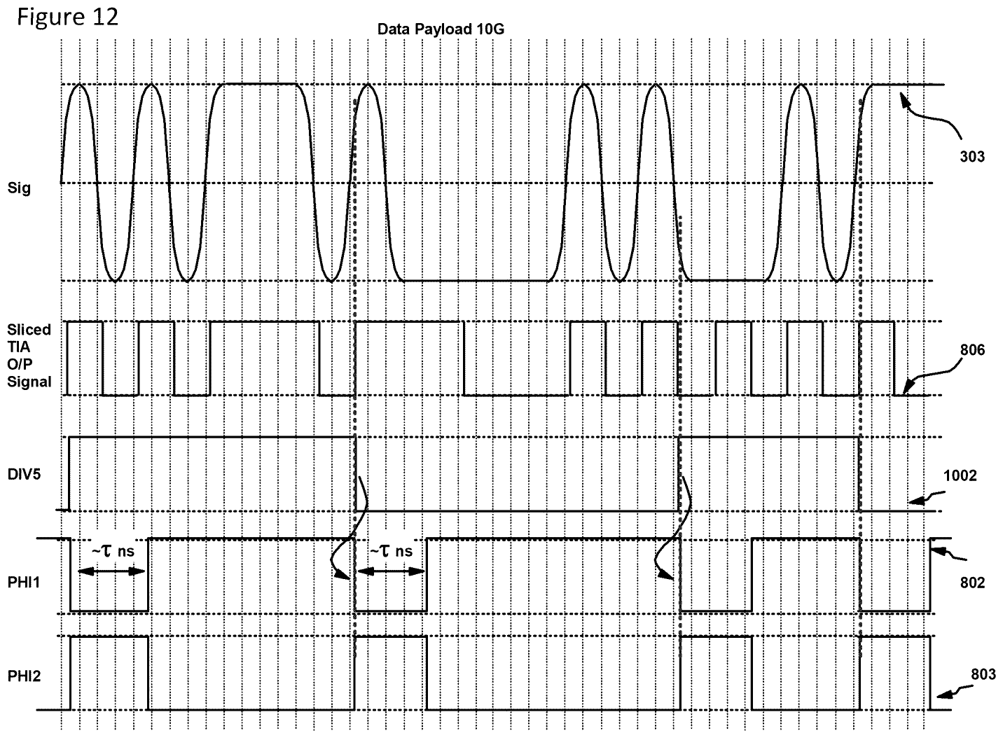

FIG. 12 further illustrates how this odd number division function 1001 can be used to provide the switched capacitor sampling clocks 802, 803, that may be used to sample the data signal waveform 303 at the output of the TIA 300 during the data payload 206. Even though the sampling clocks are no longer produced at a fixed repetition rate, but at instants fluctuating in time depending on the data stream transitions present, it can be seen that the switched capacitor sampling function 801 is still able to provide equal numbers of signal samples from the ‘1’ and ‘0’ states present in the data waveform.

It will be apparent to one skilled in the art that the successful operation of the switched capacitor sampling arrangement 801 described with reference to FIGS. 8 to 12 relies to a significant degree on having clocking signals derived from the TIA output signal 303 data stream with wherein the clocking signals so derived have well defined timing properties.

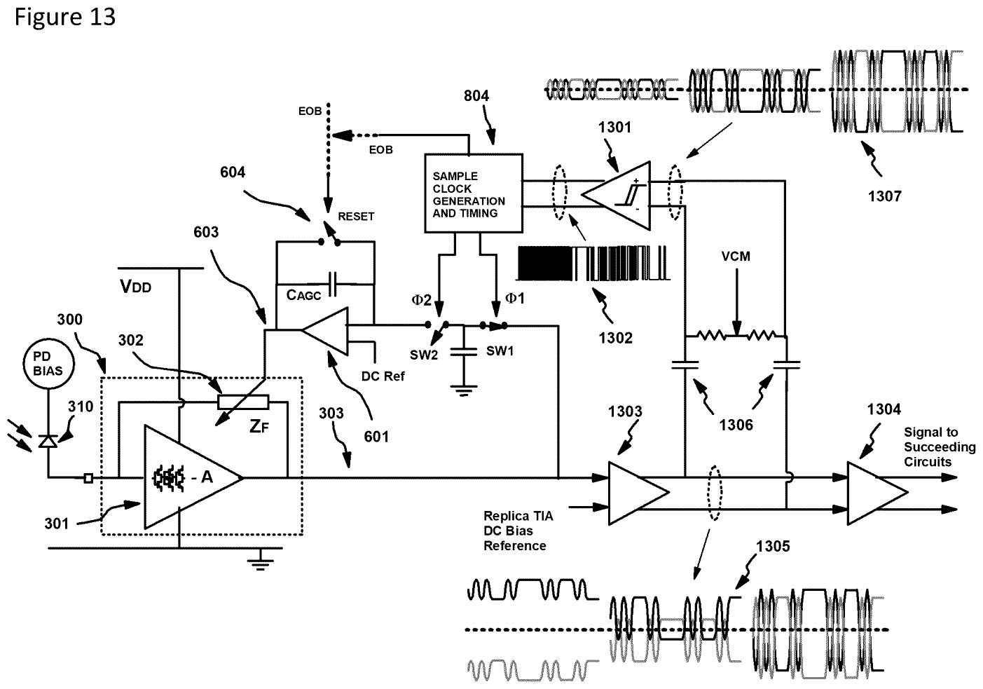

FIG. 13 shows an arrangement according to an aspect of the invention wherein there is provided a differential comparator 1301 whose function is to provide a precise sliced signal 1302 from the data signal 303 present at the output of the TIA 300. The output of the TIA core amplifier 301 may be in a single ended form, as shown in FIG. 13, and in such a situation it is conventional to use a single-ended to differential signal conversion function 1303 to provide a suitable input for succeeding functions, such as limiting amplifiers 1304, etc. In the illustrative arrangement presented in FIG. 13, the common mode level of the differential signal 1305 produced by the single-ended to differential signal conversion function 1303 is not set at any fixed level, but is allowed to vary within acceptable ranges as a result of the varying DC component of the photodiode 310 current due to different optical signal strengths. This differential signal 1305 may have a significant DC offset before being passed to the comparator 1301 via coupling capacitors 1306 so that the comparator input 1307 is effectively a symmetrical differential version of the data signal 303 at the output of the TIA 300. It is the purpose of the comparator 1301 to produce a sliced, squared waveform 1302 representing the crossing of the two complementary parts of the AC coupled differential signal 1307, said crossing points being equivalent to the mean level of the data signal waveform.

To avoid noise creating false decisions in the comparator 1301 at low signal levels, it is preferable to incorporate some degree of hysteresis in the comparator response. This will naturally mean that there is a small delay in the output waveform used to drive the switched capacitor sampling clock generation system 804, but provided that the decision level and the associated hysteresis levels of the comparator 1301 are symmetrical about the level when both inputs to the comparator are at equal levels, then the sampling timing will function correctly to ensure symmetrical sampling of the TIA output signal 303.

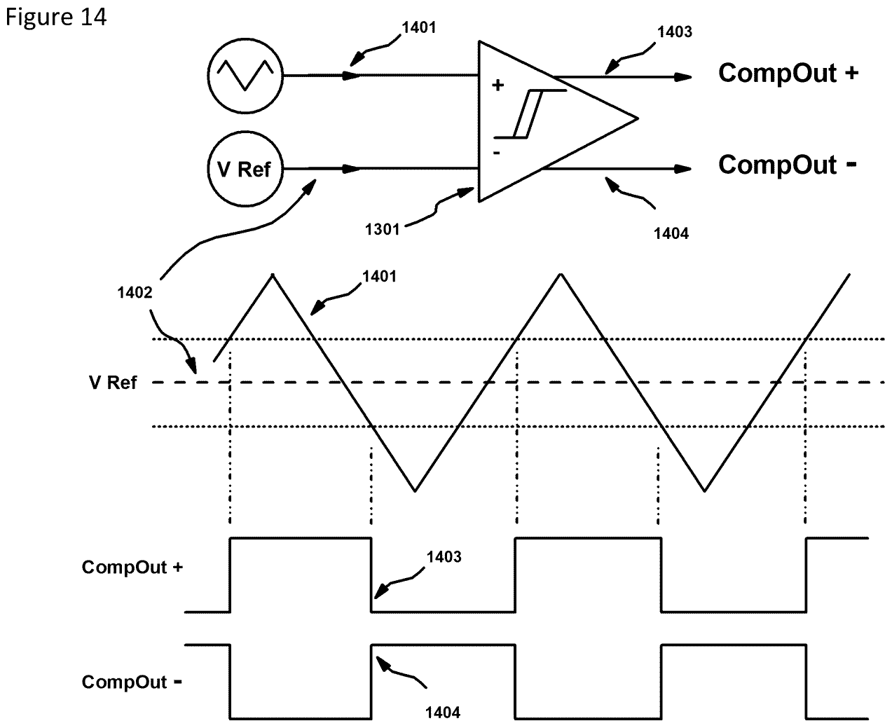

FIG. 14 illustrates the desired behaviour of the fast differential comparator 1301 used to create the sampling clocks 802, 803. With an ideal ramp signal 1401 applied to one input and a fixed reference level 1402 set at the other input, for example, at the common mode level of the ramp input, the two complementary outputs 1403, 1404 will have transitions that occur symmetrically where the positive going and negative going ramp signal 1401 crosses the reference level 1402. With this behaviour, the signals 1302, used to drive the sampling clocking circuitry 804 will provide transitions symmetrical around the crossing points of the differential input signal.

In order to ensure that the fast differential comparator 1301 provides the required precise degree of symmetry between the decisions made for both positive-going and negative-going inputs as reflected in its complementary output signals 1302, it is prudent to provide some mechanism to adjust or trim the comparator's behaviour to allow for imperfections in manufacture or variations in performance due to environmental effects. In providing a suitable adjustment or trimming capability it is noted that the behaviour of the comparator in terms of its decision levels and the magnitude of any hysteresis in its response may be different when dealing with inputs that are slowly varying, compared with signals that have very high frequency components, possibly into the range of many GHz. Such differences may be due to many factors, such as differences in transistor threshold voltages, resistances, transistor gain factors, parasitic capacitances, etc. To allow for these various factors, it is therefore preferable to provide arrangements to be able to make adjustments or perform trimming operations to optimise the performance for both slowly and rapidly varying input signals.

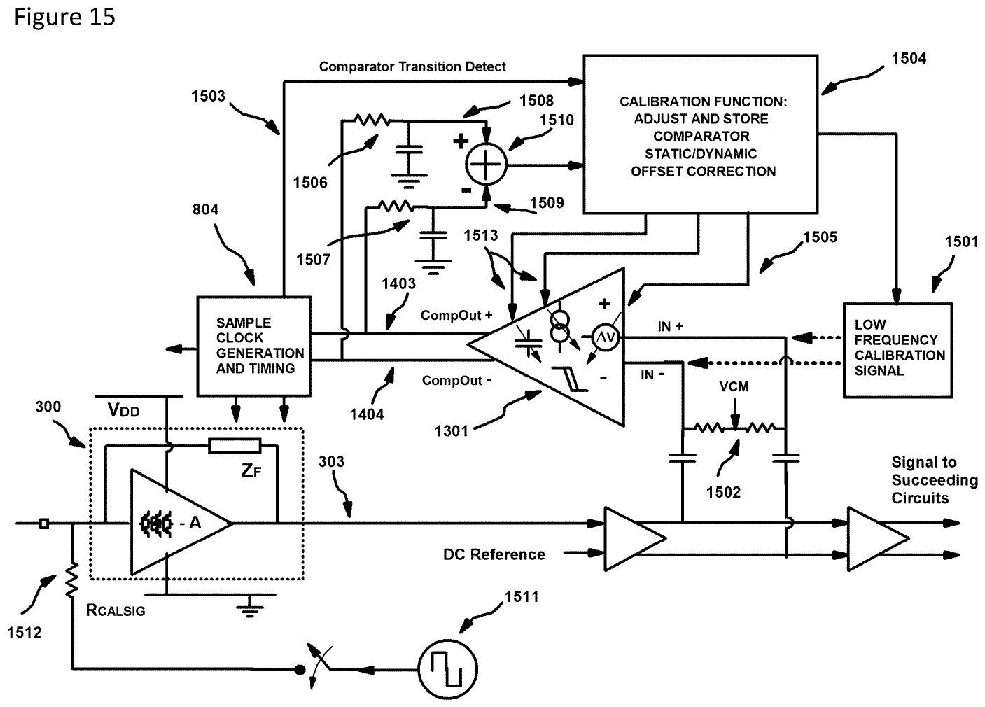

FIG. 15 shows an arrangement according to an aspect of the invention wherein there are provided means for the adjustment and trimming the behaviour of the sampling clock generation comparator 1301 for both low frequency, i.e., quasi-static, and high frequency, i.e., dynamic conditions.

The adjustment or trimming of the fast differential comparator 1301 used for generation of the sampling clocks may conveniently begin with the low frequency or quasi-static performance. With no optical input signal present in the TIA path and thus at the TIA output 303, a slowly varying precision calibration signal 1501 may be applied to one or both of the comparator input terminals. Said calibration signal may conveniently be in the form of a ramp signal 1401, such as presented diagrammatically in FIG. 14. The common mode level 1502 for the comparator inputs may conveniently be set at the normal operating level. Since said calibration signal is slowly varying in nature, it is possible to construct a source for same with a high degree of precision. At the outputs (1403, 1404) of the comparator 1301, the transitions are detected and communicated to a calibration and offset correction controller 1504.

Said calibration controller 1504 may then adjust circuit parameters 1505 within the comparator 1301 that are known to affect the low frequency behaviour, for example transistor thresholds may be adjusted by means of body bias levels, resistance values may be trimmed by digital selection, or by means of other methods known to persons skilled in the art. The calibration of the low frequency behaviour is deemed to be finished when the transitions at the comparator outputs 1403, 1404 are found to be symmetrical around the crossing point of the comparator input levels, and any hysteresis levels are observed corresponding to the desired values.

The trimming inputs 1505 required to achieve the desired low frequency behaviour are then stored in the calibration controller 1504, and the TIA system is reconfigured to perform the second part of the calibration to obtain the desired performance with rapidly varying inputs. For these operations, two simple passive low pass filter circuits 1506, 1507, are connected to the complementary outputs 1403, 1404 of the comparator 1301. Being passive in nature, these low-pass filters do not in themselves introduce any DC offset into any of the measurements. These two filter circuits 1506, 1507 may have their outputs combined in a subtraction arrangement 1510, which may be a discrete subtractor, or may be connected as differential inputs to an analogue to digital convertor (ADC), or other configuration able to detect the difference between the low-frequency levels present at the output of said filters. The result of the said subtraction operation is communicated to the calibration controller 1504. Said subtraction function (or ADC, etc.) 1501 is only required to operate at low frequencies, and hence may be readily constructed with considerable precision.

There is also provided a high frequency calibration source 1511 that may be connected to the input of the TIA 300. This may be connected via a suitable resistance 1512 to replicate the input current signal levels expected from a photodiode 310. Said calibration signal source 1511 is configured to operate at a frequency in substantially the same frequency range as would be expected for the preamble pattern 204 when in normal operation. Said calibration signal source 1511 is further configured to provide a substantially square waveform with a precise 1:1 mark:space ratio. This may be conveniently provided, for example, by a means of suitable phase-locked loop with a digital divider at its output to ensure the provision of a waveform that is symmetrical in the time domain.

This signal at the input to the TIA system is amplified and passes through the single ended to differential conversion circuits 1303 to the comparator 1301 via the AC coupling network 1306 to remove any DC offset between the two input signal branches. The outputs 1403, 1404 of the comparator 1301 should then ideally have complementary square signals each with a 1:1 mark:space ratio. Hence, DC levels at the outputs of the two passive low-pass filters should be identical. Any difference between the DC levels 1508, 1509 at the outputs of the two passive low-pass filters 1506, 1507 obtained by means of a suitable subtraction function 1510 may be detected within the calibration controller 1504. Said calibration controller 1504 may then adjust circuit parameters 1513 within the comparator that have an influence on the dynamic behaviour, for example, trimming bias currents, parasitic capacitance values may be trimmed by digital selection, or other methods known to persons skilled in the art.

The calibration of the comparator's high frequency behaviour is deemed to be finished when DC levels 1508, 1509, at the outputs of the two passive low-pass filters 1506, 1507, are sufficiently close to identical that no further improvement by the calibration process is possible. The trimming inputs 1513 determined during the calibration and trimming operation required to achieve the desired high frequency behaviour are then stored in the calibration controller 1504, and the system returned to the configuration for normal operation.

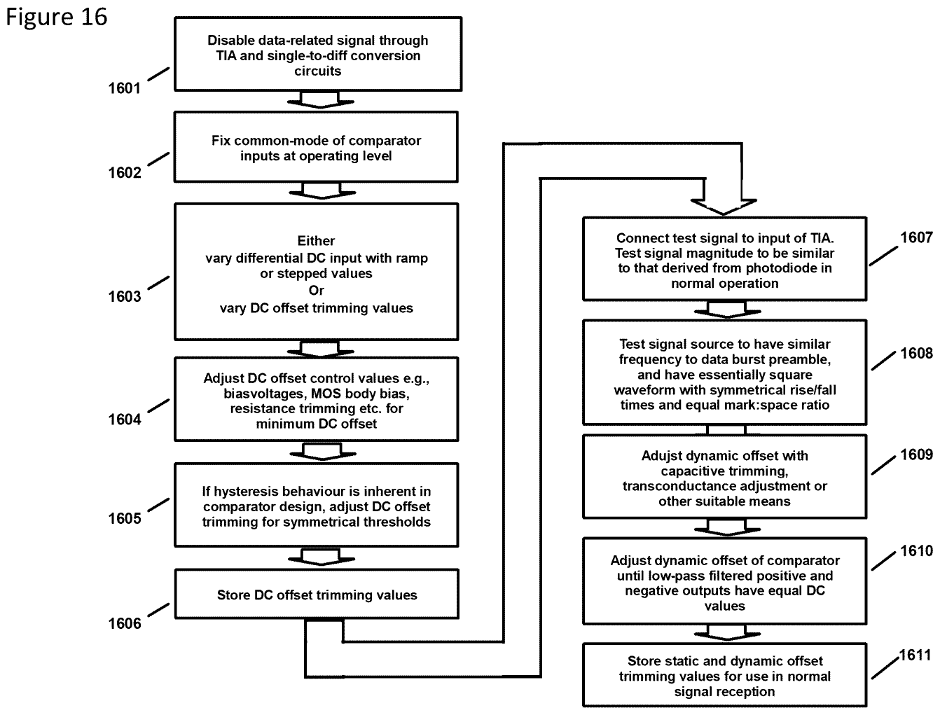

FIG. 16 shows a flow chart of an exemplar method for the calibration and trimming procedure as described above according to an aspect of the invention. It will be understood that many variations of this method and other different methods are possible to achieve the objectives of the invention.

Thus there is a first operation 1601 of disabling data-related signals through the TIA and single-ended to differential conversion circuits.

Then, 1602, the common mode level at the input of the differential comparator is fixed at the normal operating level

Then, 1603, a varying input ramp may be applied, or alternatively the DC offset parameters of the comparator may be varied

Then, 1604, the DC offset of the comparator is adjusted by trimming of such parameters as threshold voltages, resistor values, etc.

Then, 1605, if hysteresis is employed in the comparator design, adjust DC offset trimming for symmetrical thresholds.

Then, 1606, store the static DC offset trimming values

Then, 1607, connect a high frequency test signal to the input of the TIA, setting magnitude of test source to be of same order as a normal signal from a photodiode, said magnitude being sufficient to overcome any hysteresis in the comparator 1301.

Then, 1608, configure test signal to have a mark:space ratio of precisely 1:1 with symmetrical rise and fall times.

Then, 1609, adjust the comparator dynamic offset behaviour by trimming of capacitances, transconductances etc.

Then, 1610, continue to adjust the dynamic offset of the comparator until the output levels of low-pass filters coupled to the outputs of the comparator are substantially equal.

Then, 1611, store the static DC and high frequency dynamic trimming values and reconfigure the circuit for normal operation.

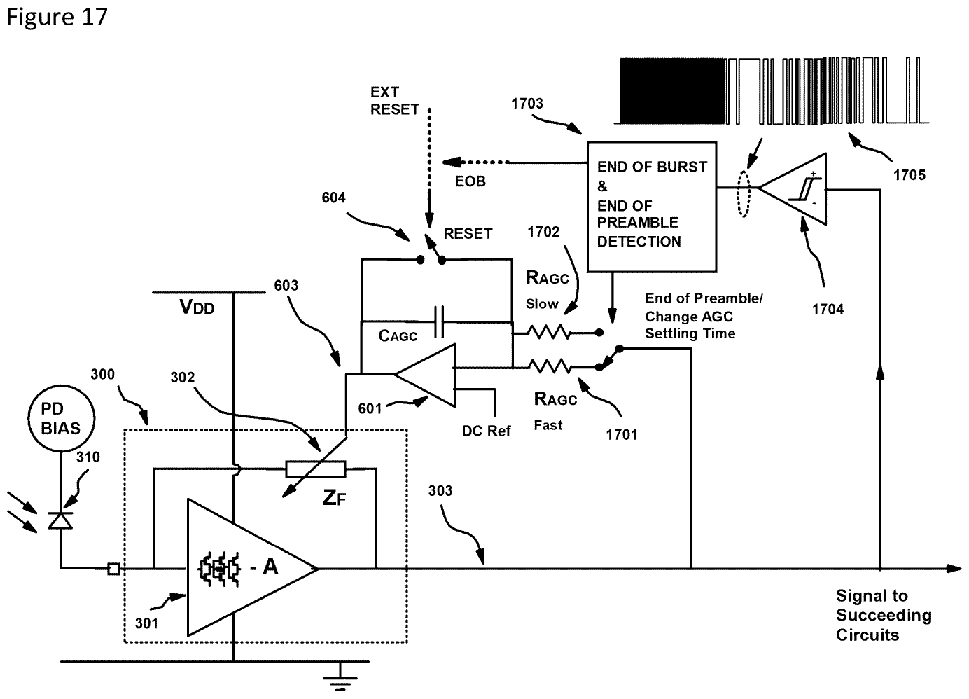

FIG. 17 shows a further arrangement for a TIA system according to an aspect of the invention wherein there is provided means to make larger discrete changes to the settling time of the AGC system. In this arrangement, when a fast settling time constant is desired, for example, during the preamble period 204 of a data burst, the output 303 of the TIA 300 is connected to an integrator 601 controlling the AGC functions via a first resistance 1701. When it is desired to change from a fast AGC settling time constant to a slow AGC settling time constant, the input path to the AGC integrator 601 from the TIA output 303 is changed to a connection via larger value resistance 1702. It will be clear to one skilled in the art that the change in the effective resistance seen between the input of the integrator and the output of the TIA may be also achieved by many other possible switching arrangements comprising series connections, parallel connections or combinations thereof.

The change from a fast AGC settling time constant to a slow AGC settling time constant may be initiated by a detection function 1703 that determines that the preamble 204 is ending and that reception of the data payload 206 is commencing. Said detection function 1703 receives a sliced version 1705 of the signal 303 present at the output of the TIA 300, said sliced signal 1705 being provided by a limiting amplifier or self-referencing comparator 1704, or by other comparable means.

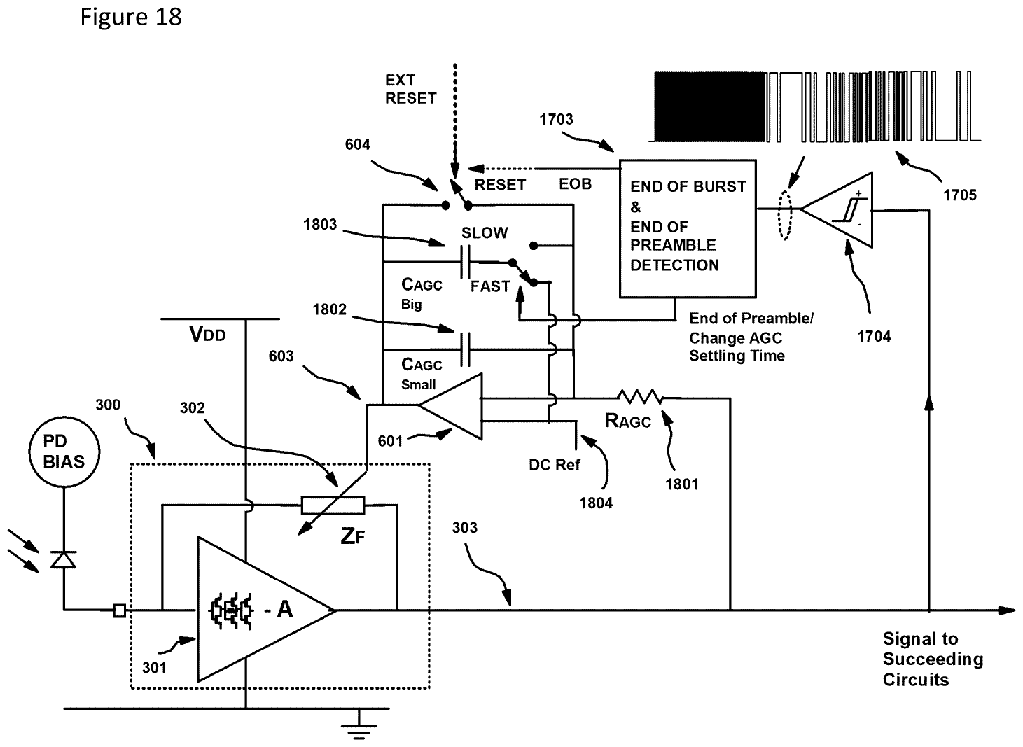

FIG. 18 shows a yet further arrangement for a TIA system according to an aspect of the invention wherein there is provided alternative means to make large discrete changes to the settling time of the AGC system. In this arrangement, the AGC integrator 601 is connected to the output 303 of the TIA 300 by means of a single resistance 1801, but in this arrangement, the AGC integrator 601 incorporates two feedback capacitors, 1802, 1803. Where a fast AGC settling time is desired, for example, during the preamble period 204 of a data burst, only a first one of the said capacitors 1802 in connected from the input to the output of the integrator 601 to accumulate charge supplied by the AGC integrator amplifier.

When it is required for the AGC to change to a slow settling time, for example at the end of the preamble when the data payload 206 commences, then a second capacitor 1803 may be connected between the input and output of the AGC integrator 601. As presented in FIG. 18, a convenient method for this switching process is to make a fixed connection of one terminal of said second capacitor 1803 to the output 603 of the AGC integrator 601, and to switch the other terminal of the said second capacitor 1803 from a reference potential 1804 used to set the virtual earth level of the AGC integrator, and then to connect that terminal of the said second capacitor 1803 to the input terminal of the AGC integrator 601. In this way, the said second capacitor 1803 will always have the correct value of stored charge whether it is connected to the input of the AGC integrator 601 not, thereby avoiding transients in the control loop in the event of a change in AGC settling time being made.

The change from a fast AGC settling time constant to a slow AGC settling time constant may be initiated as previously described by a detection function 1703 that, for example, determines that the preamble 204 is ending and that reception of the data payload 206 is commencing.

Where it is desirable to have the facility to change the AGC settling time constant when the data burst preamble 204 comes to an end as described with reference to FIGS. 17 and 18, by selecting a different feedback capacitances 1802, 1803, or different input resistances 1701, 1702, in an integrator 601 arrangement or by some other means, then there is a clear requirement to be able to determine when the preamble is ending and that reception of the data payload is commencing in order to be able to signal an appropriate time to make this change.

A possible approach for the detection of the end of the preamble would be to detect when an incoming data pattern from the start of a burst of a repetitive ‘1010’ form ceases, and more random data patterns begin, said patterns containing consecutive runs of a number of identical data symbols.

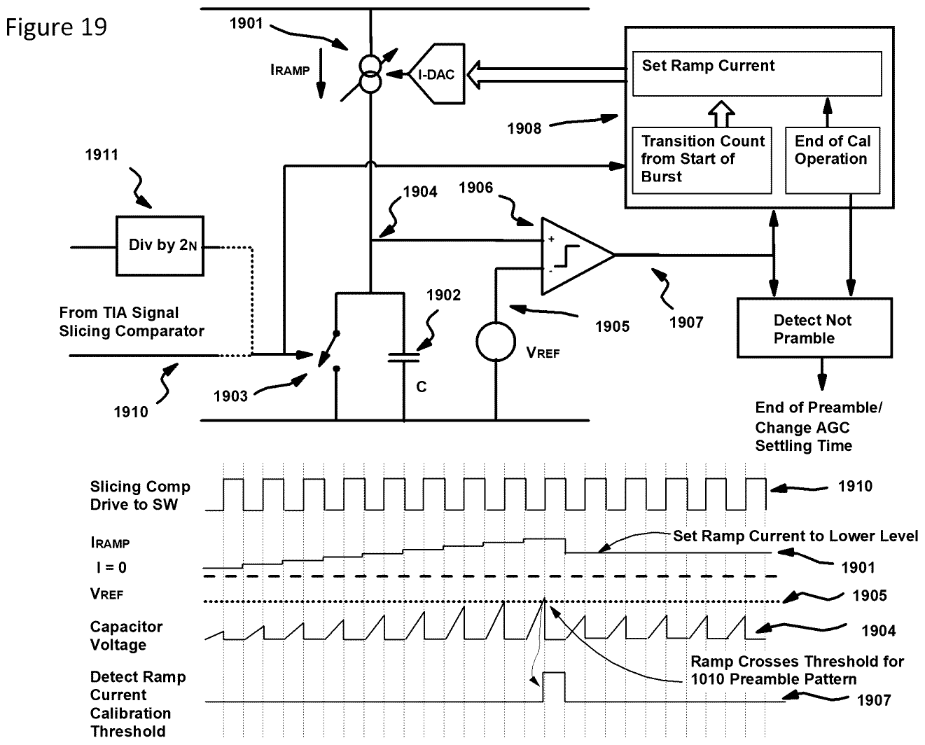

FIG. 19 shows an arrangement comprising part of the TIA system for burst mode reception wherein there are provided means for the detection of the end of a preamble sequence, by the detection of data sequences of, for example, two or more identical symbols. A problem to be addressed in such a detection system is that of defining the accuracy of the required timing functions, whilst taking account of manufacturing tolerances, power supplies, and environmental effects, etc.

The arrangement shown uses a simple ramp integrator wherein, for example, a programmable or adjustable current source 1901 charges a capacitor 1902, and wherein a switch 1903 is provided to enable the integration process to be reset. The charging process is initiated for example, on the falling edge of the output 1910 of a comparator or limiting amplifier detecting data symbol values (corresponding to the start of a ‘0’ data symbol), and is reset on the rising edge of the output 1910 of said comparator (corresponding the start of a ‘1’ data symbol).

The ramp voltage 1904 generated by the integrator is compared in a comparator 1906 with a reference voltage 1905 and an output signal 1907 generated to indicate if said reference level has been crossed. If the data symbols within the preamble are a repetitive ‘1010’ pattern, then the ramp voltage 1904 may not reach the level of the reference 1905 before it is reset by the switch 1903, and so no comparison output signal corresponding to such a crossing event is generated. If the data stream contains sequences of multiple identical symbols, the integrator ramp 1904 will not be reset after one symbol period, and the ramp voltage will rise to a higher level before being reset by the switch 1903, with the probability that the ramp voltage 1904 will cross the reference level 1905, leading to an output 1907 from the detection comparator 1906 signalling a crossing event.

There is a clear need to be able to set the circuit parameters such that the ramp voltage 1904 will not exceed the reference level 1905 within one symbol period, while guaranteeing that it will exceed the reference level if there is a larger defined number of identical symbols in the data sequence. These requirements could be addressed by adjustment of the reference level. Alternatively, the rate at which the ramp 1904 rises may be set so that it will not exceed the reference level 1905 within one symbol period, while guaranteeing that it will exceed the reference level if there is a larger defined number of identical symbols in the data sequence.

To address the abovementioned requirements, the arrangement in FIG. 19 is configured to undergo a calibration procedure at the start of each burst 204 and the illustrative waveforms indicating internal signal levels are intended to represent said calibration procedure. Provided that the burst has a suitable minimum number of symbols in the preamble sequence containing, for example, a ‘1010’ pattern, the calibration can be performed before the end of the preamble and be primed in readiness to be able to detect the beginning of the data payload 206.

In FIG. 19, the reference level 1905 connected to the negative input of the detection comparator 1906 is set to some convenient value consistent with the correct operation of said comparator, and allowing sufficient range for the integrator ramp output 1904, for example at 70% of the power supply range. At the start of a data burst, the current source 1901 is set to deliver a suitable low initial value of current and the integrator is reset by the switch 1903. During the time when the data symbol value is ‘0’, the ramp voltage 1904 rises in a linear manner. If the ramp voltage does not reach a level that exceeds the reference level 1905 before the end of the symbol period and the integrator is reset by the switch 1903, then the comparator output 1907 will indicate that the reference level has not been crossed, and the value of the current supplied by the current source 1901 is incremented under the control of a calibration system 1908. This process is repeated for succeeding data symbol periods until the integrator ramp output 1904 rises fast enough to be able to exceed the reference level 1905 within the duration of a single symbol period.

The calibration system 1908 has thus determined the necessary setting for the current source 1901 required to result in the detection comparator 1906 signalling that the reference 1905 has been crossed by the rising ramp signal 1904 within the duration of one data symbol period.

Before the next integration cycle begins, the current source 1901 output is reduced to a value that is a fraction of the current required to result in the integrator ramp 1904 crossing the reference level 1905 in one data symbol period. For example, setting the current source 1901 to a value of the order of 70% of the previous value set when detection occurred may be advantageous. Note that the new current value should not preferably be less than 50% of the previous value if it is desired to be able to detect when there are at least two consecutive identical symbols.

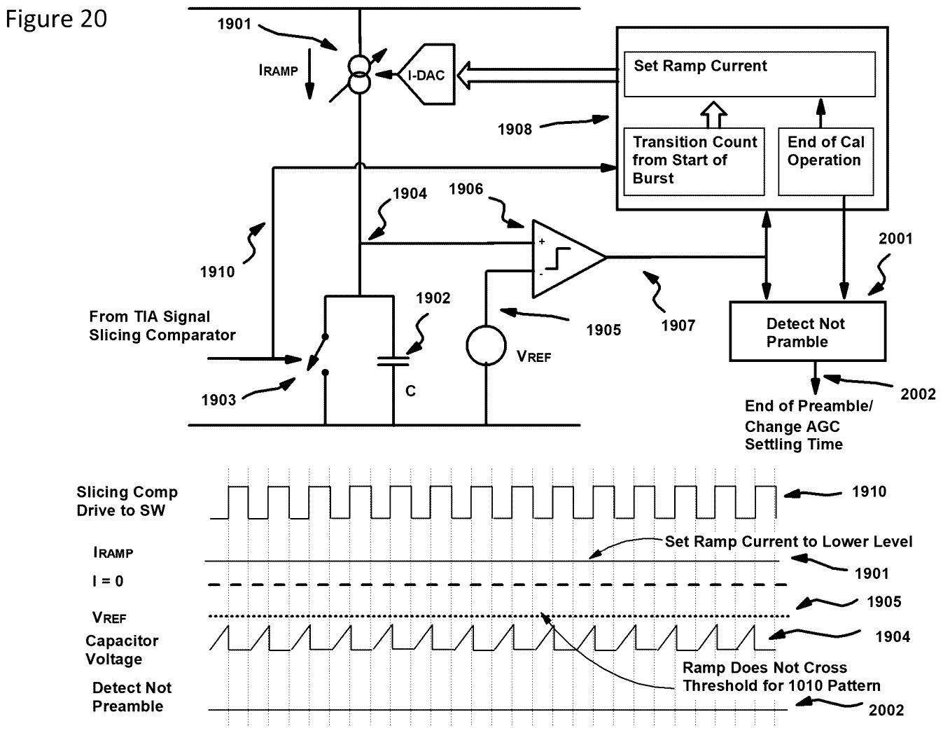

FIG. 20 illustrates the operation of the detection system after the calibration process has completed and during the remainder of the data burst preamble 204. The output of the detection comparator 1906 is combined in a logical function 2001 with the status information from the calibration system 1908 that the calibration process has ended and the system is actively monitoring for the signal conditions indicating the beginning of the data payload 206, the output of said logical function 2001 being a signal 2002 that indicates if the preamble 204 has ended or not.

The integrator ramp 1904 is started following each ‘1’ to ‘0’ transition in the incoming sliced signal 1910 and is reset by the switch 1903 on the next ‘0’ to ‘1’ transition. In this state there is now certainty that during a single symbol period the integrator ramp output 1904 cannot rise to a value greater than the reference level 1905. During the remainder of the preamble 204, the prevailing ‘1010’ pattern ensures that the integrator ramp 1904 will be reset by the switch 1903 after a single symbol period, and no end of preamble detection signal 1907 is generated by the detection comparator 1906 and thus nor by the logical function 2001 that determines that the preamble has ended and the data payload has begun.

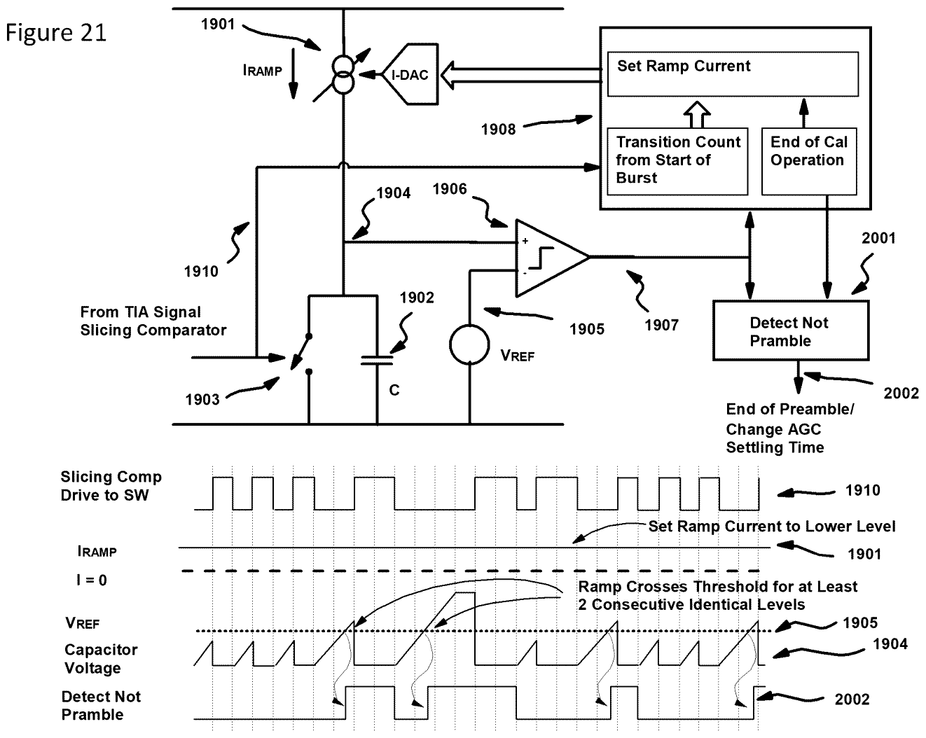

FIG. 21 illustrates the operation of the detection system when the preamble 204 ends and the data payload 206 commences. The integrator ramp 1904 is still initiated following each ‘1’ to ‘0’ transition in the incoming sliced signal 1910 and is and is reset by the switch 1903 on the next ‘0’ to ‘1’ transition. There is now the strong likelihood that a sequence of two or more consecutive identical symbols will appear in the data stream. In this situation, the integrator ramp 1904 has longer to rise before being reset by the switch 1903. For example, if there are two or more consecutive ‘0’ symbols present in the data stream, then the setting of the current source 1901 as determined by the calibration function 1908 provides enough current for the integrator ramp 1904 to exceed the reference level 1905 within the duration of two or more data symbol periods. The output 1907 of the detection comparator 1906 is then taken and combined in a logical function 2001, whose output 2002 will then indicate that the preamble 204 has ended and that the data payload 206 is being received. This end of preamble signal 2002 may then be communicated to the AGC system to trigger any desired changes in the AGC settling time constant, for example, from a fast value to a significantly slower value.

Note that the value of each increment in the current from the current source 1901 used in the calibration process should be chosen such that firstly, there is sufficient discrimination between levels where a crossing detection condition does or does not occur, and so that the calibration function can reliably set a suitable reduced current for the end of preamble detection. The current increments should not, however, be too small, otherwise the calibration procedure may not be reliably completed within a number of symbol periods that is significantly less that the total number of symbol periods allocated for the complete preamble.

For a practical realisation of the arrangement presented in FIGS. 19, 20 and 21 there are modifications and alternative arrangements that may be advantageous. Where the data rate is particularly fast, the very short symbol period associated therewith may necessitate the use of excessively large currents and small capacitances in the integrator in order to provide a ramp 1904 of sufficient scale that it can be reliably detected by a suitable detection comparator.

Provided that the programmable current source 1901 increments are chosen prudently and that the preamble employed in the system in question is sufficiently long, it may be advantageous to employ a digital divider 1911 such that the frequency of the transitions in the sliced signal input 1910 employed to reset the switch 1903 in the integrator is reduced, as shown in FIG. 19, so that the integration period before each reset is lengthened. A simple divide by 2 at the integrator reset switch 1903 input would lead to a minimum integration period of 2 symbol periods. The detection of the end of the preamble would still be possible with the arrangement described in FIGS. 19, 20 and 21, as any sequence of consecutive identical symbols will lengthen the integration period by the same duration.

In the foregoing descriptions pertaining to FIGS. 19, 20 and 21, it should be recognised that the preamble 204 pattern is assumed to be a balanced sequence of data symbols of the form ‘1010’, and detection of the end of the preamble indicated by a change to longer sequences of identical symbols. The description of the calibration and detection processes assumes that the reference timing is determined with respect to a single data symbol period, and the detection of the start of the data payload can be considered to be the detection of two or more identical data symbols. It will be obvious to one skilled in the art that the arrangements presented and described with reference to the detection of the end of the preamble may be easily configured to be able to recognise other data patterns in the preamble 204 and the payload 206 without deviating from the scope of the invention.

Further, the arrangements described with reference to FIGS. 19, 20 and 21 are described as being configured to respond to ‘1’ to ‘0’ transitions transition in the incoming sliced signal 1910 to initiate the ramp 1904 charging process, and ‘0’ to ‘1’ transitions to stop and reset the ramp charging process. One skilled in the art will recognise that adopting this simple strategy restricts the detection of sequences of identical data symbols to patterns of ‘0’ data symbols. This restriction may be easily overcome by employing a second end of preamble detection system, wherein the triggering of the start of the ramp and the end of the ramp are controlled by data value transitions of the opposite sense, and wherein the signals from these two detection systems are combined so as to indicate consecutive sequences of either ‘1’ or ‘0’ data symbols.

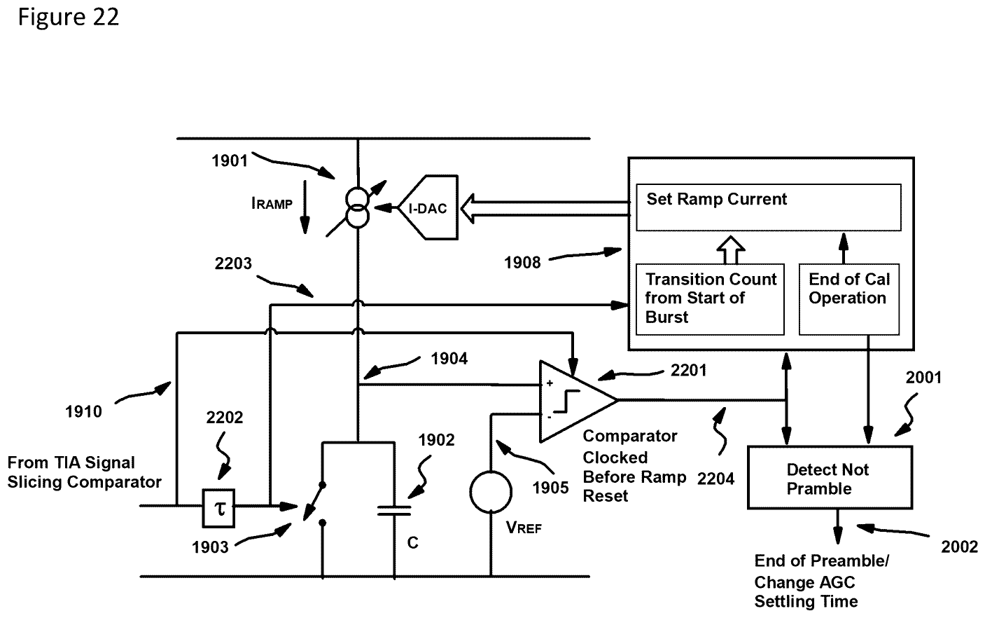

An alternative arrangement for the detection of the end of preamble is presented in FIG. 22. In this arrangement the simple ideal asynchronous detection comparator 1906 is replaced with a clocked regenerative comparator 2201. The design of an asynchronous comparator capable of making precise decisions at GHz rates is a demanding design task and typically requires that significant power is consumed therein to ensure fast operation. By contrast, clocked comparators that employ positive feedback typically require much less operating current to achieve very high-speed operation; however, this comes with the restriction that the circuit must be periodically reset, and decisions are only possible when a clock or enable signal initiates the decision process. Such a regenerative clocked comparator may be conveniently incorporated into an arrangement intended to detect the end of the preamble in a data burst with the objective of simplifying design and reducing power consumption.

In FIG. 22 there is incorporated a delay element 2202 in the clocking input 2203 to the integrator reset switch 1903. This delay element 2202 is intended to create a delay significantly shorter than a single symbol period, and its purpose is to ensure that the clocked regenerative comparator 2201 is activated a short time before the integrator is reset by the switch 1903. The output 2204 of the detection comparator 2201 is combined in a logical function 2001 with the status information from the calibration function 1908 that the calibration process has ended and the system is actively monitoring for the conditions indicating the beginning of the data payload 206, the output of said logical function 2001 being a signal 2002 that indicates if the preamble has ended or not.

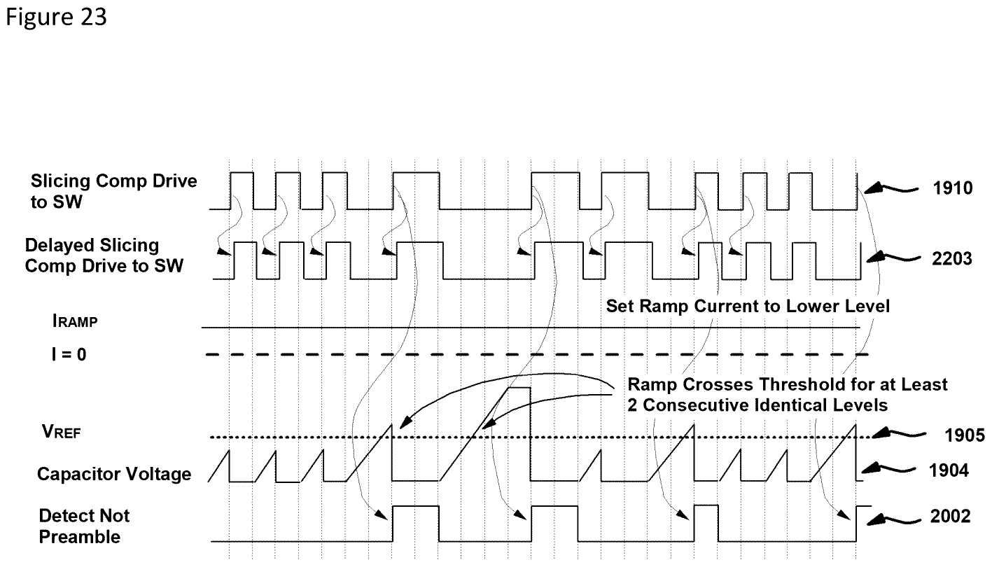

FIG. 23 is a diagrammatic presentation of the timing waveforms within the arrangement presented in FIG. 22.

An input clock 1910 is received from a slicing comparator or limiting amplifier detecting ‘1’ and ‘0’ states in the received data stream. The falling edge of this signal 1910 initiates the integration process by opening the reset switch 1903, and the integrator output 1904 will increase with a linear ramp. If the system has been through the calibration process similar to that previously described with reference to FIGS. 19, 20 and 21, and the integration current source 1901 set, then if the preamble 204 is present the integrator ramp 1904 will not have crossed the reference level 1905 before the end of the symbol period when the regenerative clocked detection comparator 2201 is activated, and the said detection comparator will not generate an output signal 2204 indicating a crossing event has occurred. Immediately after the regenerative clocked detection comparator 2201 has made a decision, the integrator is reset by the switch 1903.

If there is a sequence of more than one consecutive identical symbols after the start of the integration period, then provided that the integration current source 1901 has been set appropriately, then the integrator output ramp 1904 will cross the reference level 1905 at some time during the integration process. It will not matter if the integrator ramp 1904 saturates at its maximum level, since the regenerative clocked detection comparator 2201 is only required to determine if the crossing of the reference level 1905 has taken place; whilst the exact instant that any crossing takes place is less important. The said detection comparator output 2204 is combined in a logical function 2001 with signal from the calibration function 1908 indicating the calibration process has been completed, and will thus generate a signal 2002 indicating that the preamble 204 has ended and the data payload 206 is being received. This signal 2002 indicating that the preamble has ended may then be communicated to the AGC system to permit any desired changes in the settling time to be selected.

Note that in the foregoing the diagrams have implied that the end of preamble condition is signalled after the detection of a defined sequence (for example, more than 2 consecutive ‘0’ symbols. It will be obvious to one skilled in the art that the proposed arrangements presented in FIGS. 19, 20, 21 and 22 may be readily adapted so as to detect sequences of consecutive ‘1’ symbols to indicate that the preamble has ended and the data payload is being received. An arrangement such as is described with reference to FIGS. 19-22 detecting sequences of ‘0’ symbols may be combined with a similar arrangement detecting sequences of ‘1’ symbols for more precise detection. However, given requirements for DC balance within data streams, it is possible that only one or other of the proposed arrangements may be required in practise.

Whilst this invention has been described with reference to particular examples and possible embodiments thereof, these should not be interpreted as restricting the scope of the invention in any way. It is to be made clear that many other possible embodiments, modifications and improvements may be incorporated into or with the invention without departing from the scope and spirit of the invention as set out in the claims.

1. An assembly of electronic components for reception of data using an optical fiber wherein data is received in bursts, said assembly comprising:
a photodiode;
a transimpedance amplifier coupled to said photodiode, the gain of said transimpedance amplifier being adjusted based on a level of a gain control signal;
a received input signal sensor configured to sense a received input signal level and provide said gain control signal, said gain control signal being varied according to said received input signal level;
wherein:
said received input signal level is sensed via a sampling circuit arrangement, wherein said sampling circuit arrangement takes samples at instants dependent on the occurrence of data symbol transitions;
the speed of response of said received input sensor to changes in said received input signal level is configured to be dependent on the frequency of symbol level transitions in said received signal; and
the timing of said taking of said samples is defined to be symmetrical in time with respect to both positive and negative data symbol level transitions;
a comparator configured to detect data symbol level transitions in said received input signal and wherein an output of said comparator is configured to control the sampling instants of said sampling circuit arrangement; and
an adjustor configured to adjust a low-frequency behavior and a high-frequency behavior of said comparator so that said detection of both positive data symbol level transitions and negative data symbol level transitions in said received signal have identical behavior within accepted engineering tolerances, and wherein said adjustor further comprises:
a low-frequency calibration arrangement;
a high-frequency calibration arrangement; and
a calibration controller configured to control the configuration of the comparator into different desired modes, said modes comprising:
a normal operating mode for the reception of signals;
a low-frequency calibration mode, wherein imperfections in said comparator response to rapidly changing inputs are analyzed and corrected by said calibration controller; and
a high-frequency calibration mode, wherein imperfections in said comparator response to slowly changing inputs are analyzed and corrected by said calibration controller.

2. The assembly of claim 1, wherein said comparator has differential inputs and complementary logical outputs, and wherein:
the logical high values of each of said complementary outputs are identical within accepted engineering limits, and
the logical low values of each of said complementary outputs are identical within accepted engineering limits.

3. The assembly of claim 1, wherein at least one input of said comparator is connected to said received signal via at least one capacitor.

4. The assembly of claim 1, wherein at least one input of said comparator is configured to be disconnected from said received signal and configured to receive a low-frequency ramp calibration input, said low-frequency ramp calibration input having defined levels.

5. The assembly of claim 1, wherein said low-frequency calibration arrangement is configured to analyze decisions of said comparator generated in response to said low-frequency ramp calibration input.

6. The assembly of claim 5, wherein said low-frequency calibration arrangement is configured to reduce any lack of symmetry between positive going and negative going decision levels of said comparator to a negligible magnitude by adjustment of said adjustor under control of said calibration controller.

7. The assembly of claim 2, wherein:
said high-frequency calibration arrangement further comprises a passive low-pass filter connected to each of the complementary outputs of said comparator, and
a cut-off frequency of said passive low-pass filter is significantly below a lowest frequency component expected in said received signal when said assembly of electronic components is configured to receive said signals.

8. The assembly of claim 2, wherein an input from said photodiode is disconnected and a high-frequency test signal is applied to an input of said transimpedance amplifier.

9. The assembly of claim 8, wherein said high frequency calibration arrangement further comprises a high-frequency signal source, said high-frequency signal source providing said high-frequency test signal, said high-frequency test signal having:
a frequency comparable with a frequency of a preamble pattern that occurs in said data bursts,
a magnitude comparable with a magnitude of a signal received from said photodiode, and
a substantially square waveform with a mark:space ratio that is equal within accepted engineering tolerances.

10. The assembly of claim 7, wherein outputs of said passive low-pass filters are compared and a difference between a DC level present on each passive low-passive filter output is passed to said calibration controller, said high-frequency calibration arrangement being configured to be able to reduce a difference between DC levels of said outputs of said low-pass filters to a negligibly small value by adjustment of said adjustor under the control of said calibration controller.

11. A method for the reception of data using an optical fiber wherein data is received in bursts, said method comprising:
providing a photodiode of an assembly of electronic components;
providing a transimpedance amplifier of the assembly, the transimpedance amplifier coupled to said photodiode, the gain of said transimpedance amplifier being adjusted based on a level of a gain control signal;
providing a received input signal sensor of the assembly, the received input signal sensor configured to sense a received input signal level and provide said gain control signal, said gain control signal being varied according to said received input signal level; wherein:
said received input signal level is sensed via a sampling circuit arrangement taking samples at instants dependent on the occurrence of data symbol transitions;
the speed of response of said received input sensor to changes in said received input signal level is dependent on the frequency of symbol level transitions in said received signal; and
the timing of said sampling is arranged so that the taking of said samples is defined to be symmetrical in time with respect to both positive and negative data symbol level transitions;
providing a comparator of the assembly, the comparator configured to detect data symbol level transitions in said received input signal and wherein an output of said comparator is configured to control the sampling instants of said sampling circuit arrangement; and
providing an adjustor of the assembly for adjusting a low-frequency behavior and a high-frequency behavior of said comparator so that said detection of both positive data symbol level transitions and negative data symbol level transitions in said received signal have identical behavior within accepted engineering tolerances, and wherein said adjustor further comprises:
a low-frequency calibration arrangement;
a high-frequency calibration arrangement; and
a calibration controller, configured to control the configuration of the comparator into different desired modes, said modes comprising:
a normal operating mode for the reception of signals;
a low-frequency calibration mode, wherein imperfections in said comparator response to rapidly changing inputs are analyzed and corrected by said calibration controller; and
a high-frequency calibration mode, wherein imperfections in said comparator response to slowly changing inputs are analyzed and corrected by said calibration controller.

12. The method as claimed in claim 11, wherein said comparator has differential inputs and complementary logical outputs, and wherein:
the logical high values of each of said complementary outputs are identical within accepted engineering limits, and
the logical low values of each of said complementary outputs are identical within accepted engineering limits.

13. The method as claimed in claim 11, wherein at least one input of said comparator is connected to said received signal via at least one capacitor.

14. The method as claimed in claim 11 wherein at least one input of said comparator is configured to be disconnected from said received signal and configured to receive a low-frequency ramp calibration input, said low-frequency ramp calibration input having defined levels.

15. The method as claimed in claim 14, wherein said low-frequency calibration arrangement is configured to analyze decisions of said comparator generated in response to said low-frequency ramp calibration input.

16. The method as claimed in claim 15, wherein said low-frequency calibration arrangement is further configured to reduce any lack of symmetry between positive going decision levels and negative going decision levels of said comparator to a negligible magnitude by adjustment of said adjustor under control of said calibration controller.

17. The method as claimed in claim 12, wherein:
said high-frequency calibration arrangement comprises a passive low-pass filter connected to each of the complementary outputs of said comparator, and
a cut-off frequency of said passive low-pass filter is significantly below a lowest frequency component expected in said received signal when said assembly of electronic components is configured to receive said signals.

18. The method as claimed in claim 17 wherein an input from said photodiode is disconnected and a high-frequency test signal is applied to an input of said transimpedance amplifier.

19. The method as claimed in claim 18, wherein said high-frequency calibration arrangement further comprises a high-frequency signal source, said high-frequency signal source providing said high-frequency test signal, said high-frequency test signal having:
a frequency comparable with a frequency of a preamble pattern that occurs in said data bursts,
a magnitude comparable with a magnitude of a signal received from said photodiode, and
a substantially square waveform with a mark:space ratio that is equal within accepted engineering tolerances.

20. The method as claimed in claim 18, further comprising:
comparing outputs of said passive low-pass filters;
passing to said calibration controller a difference between a DC level present on each passive low-passive filter output;
reducing, with said high-frequency calibration arrangement, a difference between DC levels of said outputs of said low-pass filters to a negligibly small value by adjustment of said adjustor under the control of said calibration controller.
